(19) United States
(12) Patent Application Publication
(10) Pub. No.: US 2019/0237470 A1
(43) Pub. Date: Aug. 1, 2019

(54) VERTICAL 1T FERROELECTRIC MEMORY CELLS, MEMORY ARRAYS AND METHODS OF FORMING THE SAME

(71) Applicant: SanDisk Technologies LLC, Plano, TX (US)

(72) Inventors: Teruyuki Mine, Yokkaichi (JP); Christopher J. Petti, Mountain View, CA (US)

(73) Assignee: SanDisk Technologies LLC, Plano, TX (US)

(21) Appl. No.: 15/884,725

(22) Filed: Jan. 31, 2018

(51) Int. Cl. H01L 27/1159; H01L 29/78; H01L 29/66; H01L 27/11597; G11C 11/22; H01L 29/51

(52) U.S. Cl. CPC H01L 27/1159; H01L 29/7827; H01L 29/6684; H01L 29/516; H01L 29/78391; H01L 27/11597; G11C 11/22; H01L 29/66666

(57) ABSTRACT

A memory cell is provided that includes a vertical transistor having a gate oxide that includes a ferroelectric material.

### BACKGROUND

Semiconductor memory is widely used in various electronic devices such as mobile computing devices, mobile phones, solid-state drives, digital cameras, personal digital assistants, medical electronics, servers, and non-mobile computing devices. Semiconductor memory may include non-volatile memory or volatile memory. A non-volatile memory device allows information to be stored or retained even when the non-volatile memory device is not connected to a source of power (e.g., a battery).

Examples of non-volatile memory include flash memory (e.g., NAND-type and NOR-type flash memory), Electrically Erasable Programmable Read-Only Memory (EEPROM), ferroelectric memory (e.g., FeRAM), magnetoresistive memory (e.g., MRAM), and phase change memory (e.g., PRAM). In recent years, non-volatile memory devices have been scaled to reduce the cost per bit. However, as process geometries shrink, many design and process challenges are presented.

### BRIEF DESCRIPTION OF THE DRAWINGS

FIG. 1A depicts an embodiment of a memory system and a host.

FIG. 1B depicts an embodiment of memory core control circuits.

FIG. 1C depicts an embodiment of a memory core.

FIG. 1D depicts an embodiment of a memory bay.

FIG. 1E depicts an embodiment of a memory block.

FIG. 1F depicts another embodiment of a memory bay.

FIG. 2A depicts an embodiment of a portion of a monolithic three-dimensional memory array.

FIG. 2B depicts an example electrical characteristic of a ferroelectric field effect transistor.

FIGS. 2C-2E depict an embodiment of a first memory level, a second memory level, and a third memory level, respectively, of the memory array of FIG. 2A

FIGS. 2F-2H depict perspective views of an embodiment of a first row, a second row and a third row of the first memory level of FIG. 2C.

FIGS. 3A-3C depict various views of an embodiment monolithic three-dimensional memory array.

FIGS. 4A1-4K4 are cross-sectional views of a portion of a substrate during an example fabrication of the memory array of FIGS. 3A-3C.

### DETAILED DESCRIPTION

Vertical single-transistor (1T) memory elements, memory arrays of vertical 1T memory elements, and monolithic three-dimension memory arrays of vertical 1T memory elements are described. In particular, memory elements are described that include a vertical transistor having a gate oxide that includes a ferroelectric material. In an embodiment, the ferroelectric material includes hafnium oxide.

In one embodiment, a non-volatile storage system may include one or more two-dimensional arrays of non-volatile memory cells. The memory cells within a two-dimensional memory array may form a single layer of memory cells and may be selected via control lines (e.g., bit lines, source lines and word lines) in the X and Y directions. In another embodiment, a non-volatile storage system may include one or more monolithic three-dimensional memory arrays in which two or more layers of memory cells may be formed above a single substrate without any intervening substrates. In some cases, a three-dimensional memory array may include one or more vertical columns of memory cells located above and orthogonal to a substrate.

In some embodiments, a non-volatile storage system may include a non-volatile memory that is monolithically formed in one or more physical levels of arrays of memory cells having an active area disposed above a silicon substrate. The non-volatile storage system may also include circuitry associated with the operation of the memory cells (e.g., decoders, state machines, page registers, or control circuitry for controlling the reading or programming of the memory cells). The circuitry associated with the operation of the memory cells may be located above the substrate or located within the substrate.

In some embodiments, a non-volatile storage system may include a monolithic three-dimensional memory array. The monolithic three-dimensional memory array may include one or more levels of memory cells. Each memory cell within a first level of the one or more levels of memory cells may include an active area that is located above a substrate (e.g., above a single-crystal substrate or a crystalline silicon substrate). In one example, the active area may include a semiconductor junction (e.g., a P-N junction). The active area may include a portion of a source or drain region of a transistor. In another example, the active area may include a channel region of a transistor.

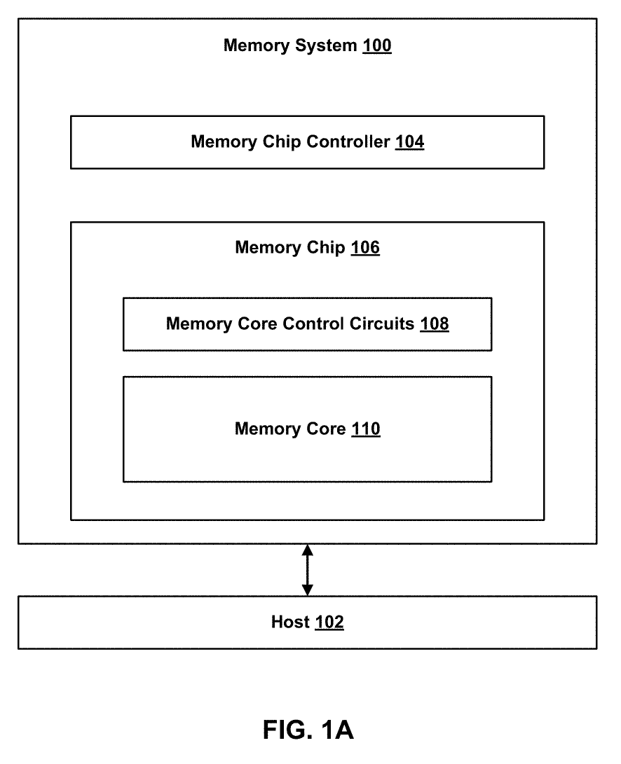

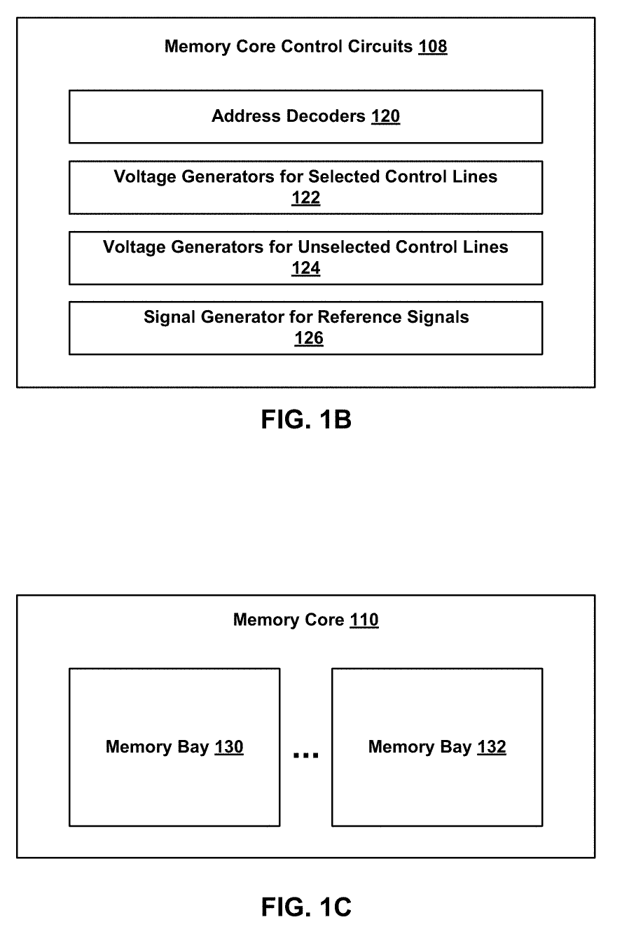

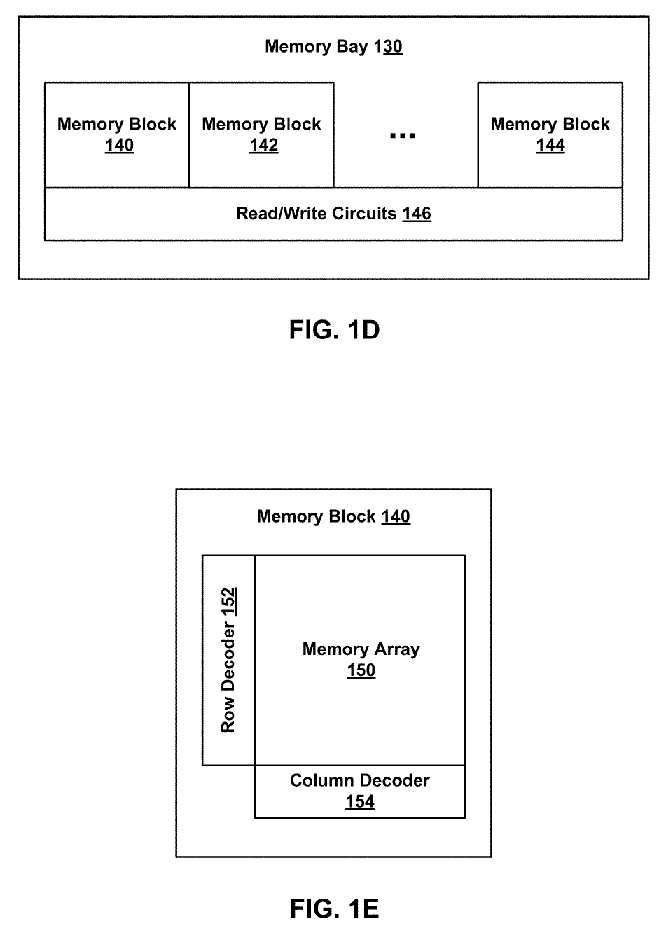

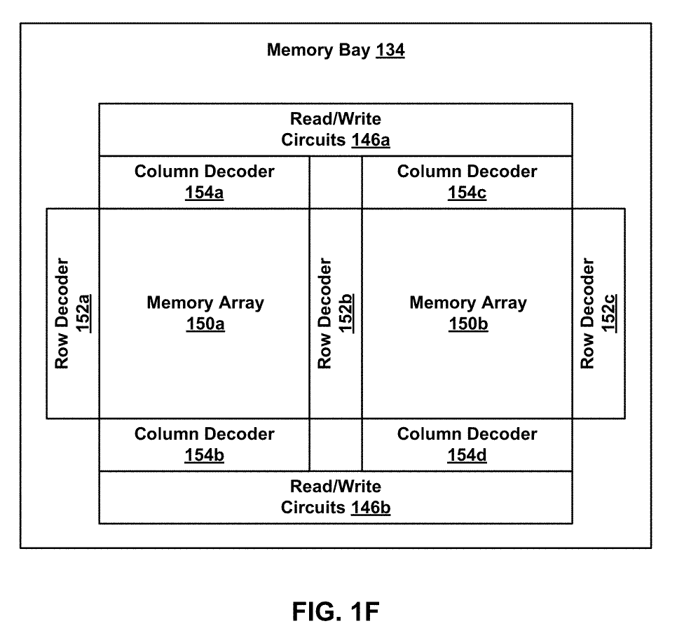

FIG. 1A depicts one embodiment of a memory system 100 and a host 102. Memory system 100 may include a non-volatile storage system interfacing with host 102 (e.g., a mobile computing device). In some cases, memory system 100 may be embedded within host 102. In other cases, memory system 100 may include a memory card. As depicted, memory system 100 includes a memory chip controller 104 and a memory chip 106. Although a single memory chip 106 is depicted, memory system 100 may include more than one memory chip (e.g., four, eight or some other number of memory chips). Memory chip controller 104 may receive data and commands from host 102 and provide memory chip data to host 102.

Memory chip controller 104 may include one or more state machines, page registers, SRAM, and control circuitry for controlling the operation of memory chip 106. The one or more state machines, page registers, SRAM, and control circuitry for controlling the operation of memory chip 106 may be referred to as managing or control circuits. The managing or control circuits may facilitate one or more memory array operations, such as forming, erasing, programming, or reading operations.

In some embodiments, the managing or control circuits (or a portion of the managing or control circuits) for facilitating one or more memory array operations may be integrated within memory chip 106. Memory chip controller 104 and memory chip 106 may be arranged on a single integrated circuit. In other embodiments, memory chip controller 104 and memory chip 106 may be arranged on different integrated circuits. In some cases, memory chip controller 104 and memory chip 106 may be integrated on a system board, logic board, or a PCB.

Memory chip 106 includes memory core control circuits 108 and a memory core 110. Memory core control circuits 108 may include logic for controlling the selection of memory blocks (or arrays) within memory core 110, controlling the generation of voltage references for biasing a particular memory array into a read or write state, or generating row and column addresses.

Memory core 110 may include one or more two-dimensional arrays of memory cells or one or more three-dimensional arrays of memory cells. In one embodiment, memory core control circuits 108 and memory core 110 are arranged on a single integrated circuit. In other embodiments, memory core control circuits 108 (or a portion of memory core control circuits 108) and memory core 110 may be arranged on different integrated circuits.

A memory operation may be initiated when host 102 sends instructions to memory chip controller 104 indicating that host 102 would like to read data from memory system 100 or write data to memory system 100. In the event of a write (or programming) operation, host 102 will send to memory chip controller 104 both a write command and the data to be written. The data to be written may be buffered by memory chip controller 104 and error correcting code (ECC) data may be generated corresponding with the data to be written. The ECC data, which allows data errors that occur during transmission or storage to be detected and/or corrected, may be written to memory core 110 or stored in non-volatile memory within memory chip controller 104. In one embodiment, the ECC data are generated and data errors are corrected by circuitry within memory chip controller 104.

Memory chip controller 104 controls operation of memory chip 106. In one example, before issuing a write operation to memory chip 106, memory chip controller 104 may check a status register to make sure that memory chip 106 is able to accept the data to be written. In another example, before issuing a read operation to memory chip 106, memory chip controller 104 may pre-read overhead information associated with the data to be read. The overhead information may include ECC data associated with the data to be read or a redirection pointer to a new memory location within memory chip 106 in which to read the data requested. Once a read or write operation is initiated by memory chip controller 104, memory core control circuits 108 may generate the appropriate bias voltages for bit lines, source lines and word lines within memory core 110, and generate the appropriate memory block, row, and column addresses.

In some embodiments, one or more managing or control circuits may be used for controlling the operation of a memory array. The one or more managing or control circuits may provide control signals to a memory array to perform a read operation and/or a write operation on the memory array. In one example, the one or more managing or control circuits may include any one of or a combination of control circuitry, state machine, decoders, sense amplifiers, read/write circuits, and/or controllers. The one or more managing circuits may perform or facilitate one or more memory array operations including erasing, programming, or reading operations. In one example, one or more managing circuits may include an on-chip memory controller for determining row and column address, bit line, source line and word line addresses, memory array enable signals, and data latching signals.

FIG. 1B depicts an embodiment of memory core control circuits 108. As depicted, memory core control circuits 108 include address decoders 120, voltage generators for selected control lines 122, voltage generators for unselected control lines 124 and signal generators for reference signals 126 (described in more detail below). Control lines may include bit lines, source lines and word lines, or a combination of bit lines, source lines and word lines. Selected control lines may include selected bit lines, selected source lines and/or selected word lines that are used to place memory cells into a selected state. Unselected control lines may include unselected bit lines, unselected source lines and/or unselected word lines that are used to place memory cells into an unselected state.

Address decoders 120 may generate memory block addresses, as well as row addresses and column addresses for a particular memory block. Voltage generators (or voltage regulators) for selected control lines 122 may include one or more voltage generators for generating selected control line voltages. Voltage generators for unselected control lines 124 may include one or more voltage generators for generating unselected control line voltages. Signal generators for reference signals 126 may include one or more voltage and/or current generators for generating reference voltage and/or current signals.

FIGS. 1C-1F depict an embodiment of a memory core organization that includes a memory core having multiple memory bays, and each memory bay having multiple memory blocks. Although a memory core organization is disclosed where memory bays include memory blocks, and memory blocks include a group of memory cells, other organizations or groupings also can be used with the technology described herein.

FIG. 1C depicts one embodiment of memory core 110 in FIG. 1A. As depicted, memory core 110 includes memory bay 130 and memory bay 132. In some embodiments, the number of memory bays per memory core can be different for different implementations. For example, a memory core may include only a single memory bay or multiple memory bays (e.g., 16 or other number of memory bays).

FIG. 1D depicts one embodiment of memory bay 130 in FIG. 1C. As depicted, memory bay 130 includes memory blocks 140-144 and read/write circuits 146. In some embodiments, the number of memory blocks per memory bay may be different for different implementations. For example, a memory bay may include one or more memory blocks (e.g., 32 or other number of memory blocks per memory bay). Read/write circuits 146 include circuitry for reading and writing memory cells within memory blocks 140-144.

As depicted, read/write circuits 146 may be shared across multiple memory blocks within a memory bay. This allows chip area to be reduced because a single group of read/write circuits 146 may be used to support multiple memory blocks. However, in some embodiments, only a single memory block may be electrically coupled to read/write circuits 146 at a particular time to avoid signal conflicts.

In some embodiments, read/write circuits 146 may be used to write one or more pages of data into memory blocks 140-144 (or into a subset of the memory blocks). The memory cells within memory blocks 140-144 may permit direct over-writing of pages (i.e., data representing a page or a portion of a page may be written into memory blocks 140-144 without requiring an erase or reset operation to be performed on the memory cells prior to writing the data).

In one example, memory system 100 in FIG. 1A may receive a write command including a target address and a set of data to be written to the target address. Memory system 100 may perform a read-before-write (RBW) operation to read the data currently stored at the target address and/or to acquire overhead information (e.g., ECC information) before performing a write operation to write the set of data to the target address.

In some cases, read/write circuits 146 may be used to program a particular memory cell to be in one of three or more data states (i.e., the particular memory cell may include a multi-level memory cell). In one example, read/write circuits 146 may apply a first voltage difference (e.g., 2V) across the particular memory cell to program the particular memory cell into a first state of the three or more data states or a second voltage difference (e.g., 1V) across the particular memory cell that is less than the first voltage difference to program the particular memory cell into a second state of the three or more data states.

Applying a smaller voltage difference across the particular memory cell may cause the particular memory cell to be partially programmed or programmed at a slower rate than when applying a larger voltage difference. In another example, read/write circuits 146 may apply a first voltage difference across the particular memory cell for a first time period (e.g., 150 ns) to program the particular memory cell into a first state of the three or more data states or apply the first voltage difference across the particular memory cell for a second time period less than the first time period (e.g., 50 ns). One or more programming pulses followed by a memory cell verification phase may be used to program the particular memory cell to be in the correct state.

FIG. 1E depicts one embodiment of memory block 140 in FIG. 1D. As depicted, memory block 140 includes a memory array 150, row decoder 152, and column decoder 154. Memory array 150 may include a contiguous group of memory cells having contiguous word lines and bit lines. Memory array 150 may include one or more layers of memory cells. Memory array 150 may include a two-dimensional memory array or a three-dimensional memory array.

Row decoder 152 decodes a row address and selects a particular word line in memory array 150 when appropriate (e.g., when reading or writing memory cells in memory array 150). Column decoder 154 decodes a column address and selects one or more bit lines in memory array 150 to be electrically coupled to read/write circuits, such as read/write circuits 146 in FIG. 1D. In one embodiment, the number of word lines is 4K per memory layer, the number of bit lines is 1K per memory layer, and the number of memory layers is 4, providing a memory array 150 containing 16K memory cells.

FIG. 1F depicts one embodiment of a memory bay 134. Memory bay 134 is one example of an alternative implementation for memory bay 130 in FIG. 1D. In some embodiments, row decoders, column decoders, and read/write circuits may be split or shared between memory arrays. As depicted, row decoder 152b is shared between memory arrays 150a and 150b because row decoder 152b controls word lines in both memory arrays 150a and 150b (i.e., the word lines driven by row decoder 152b are shared).

Row decoders 152a and 152b may be split such that even word lines in memory array 150a are driven by row decoder 152a and odd word lines in memory array 150a are driven by row decoder 152b. Row decoders 152c and 152b may be split such that even word lines in memory array 150b are driven by row decoder 152c and odd word lines in memory array 150b are driven by row decoder 152b.

Column decoders 154a and 154b may be split such that even bit lines in memory array 150a are controlled by column decoder 154b and odd bit lines in memory array 150a are driven by column decoder 154a. Column decoders 154c and 154d may be split such that even bit lines in memory array 150b are controlled by column decoder 154d and odd bit lines in memory array 150b are driven by column decoder 154c.

The selected bit lines controlled by column decoder 154a and column decoder 154c may be electrically coupled to read/write circuits 146a. The selected bit lines controlled by column decoder 154b and column decoder 154d may be electrically coupled to read/write circuits 146b. Splitting the read/write circuits into read/write circuits 146a and 146b when the column decoders are split may allow for a more efficient layout of the memory bay.

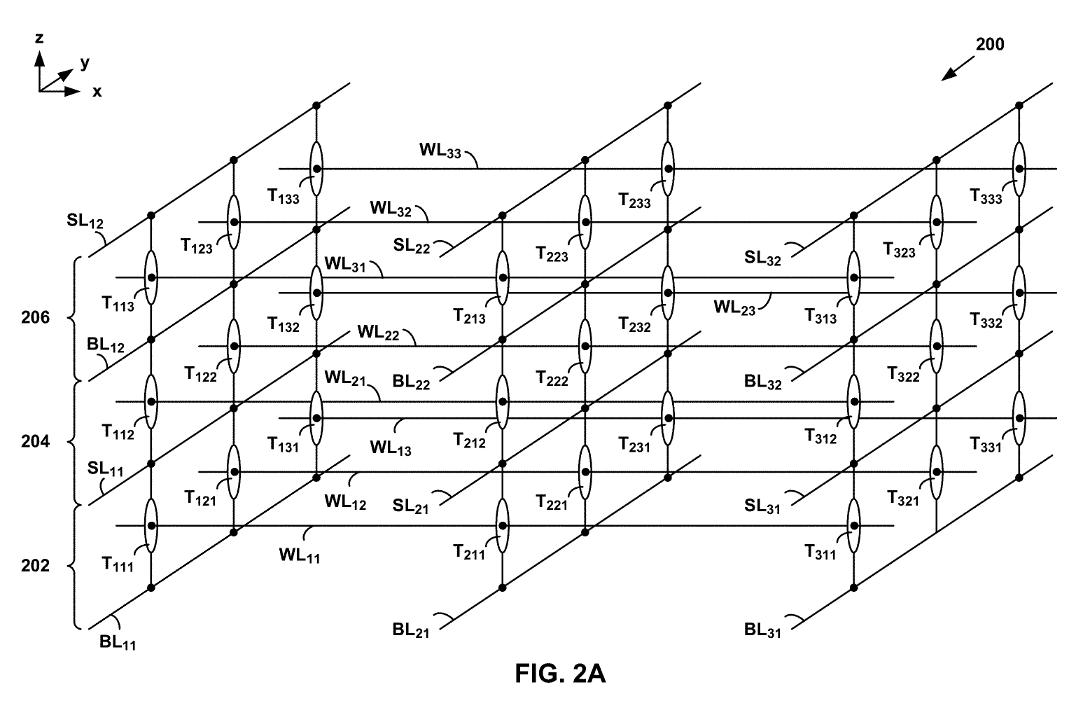

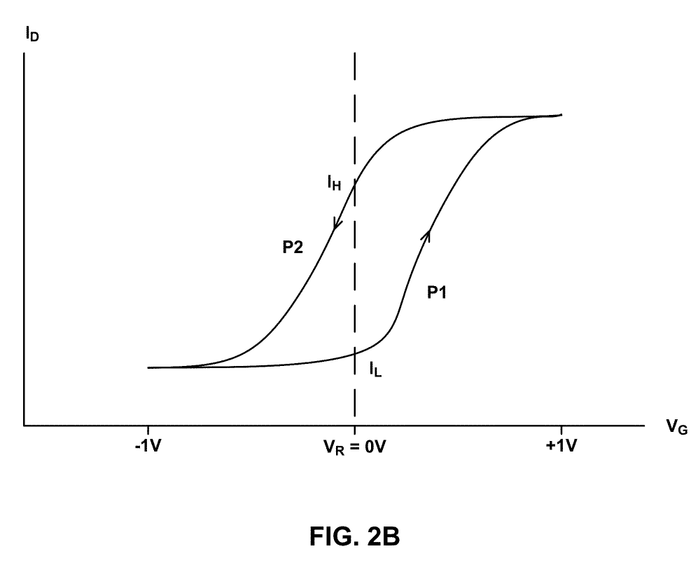

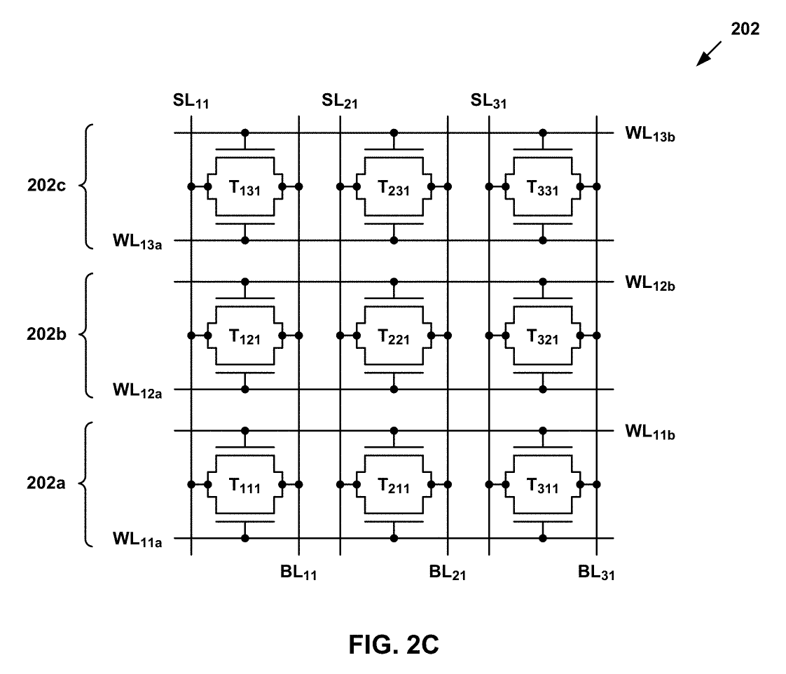

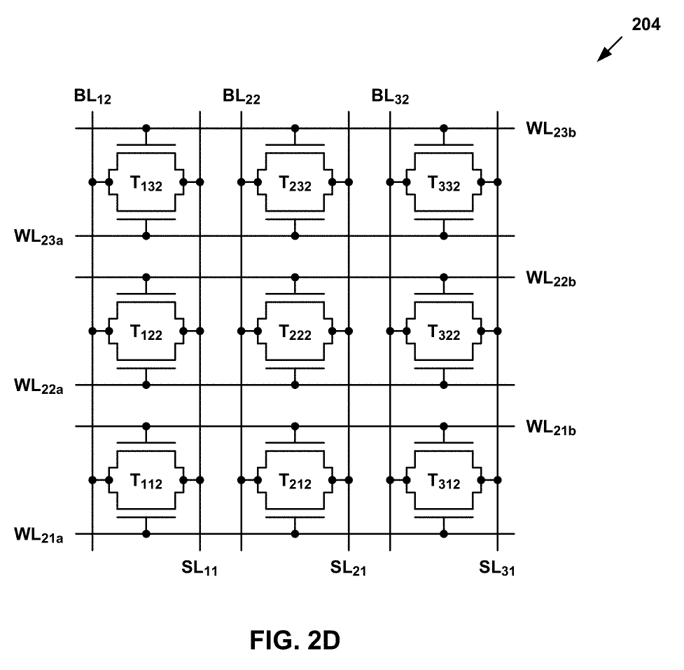

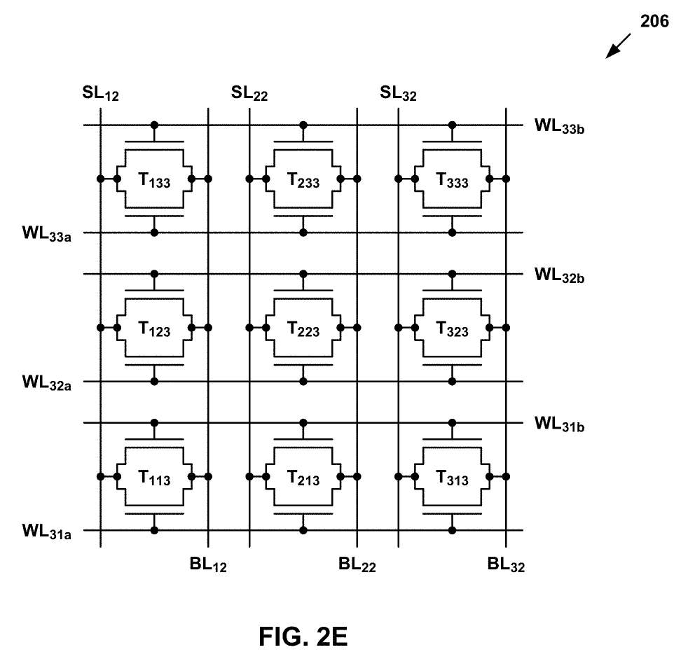

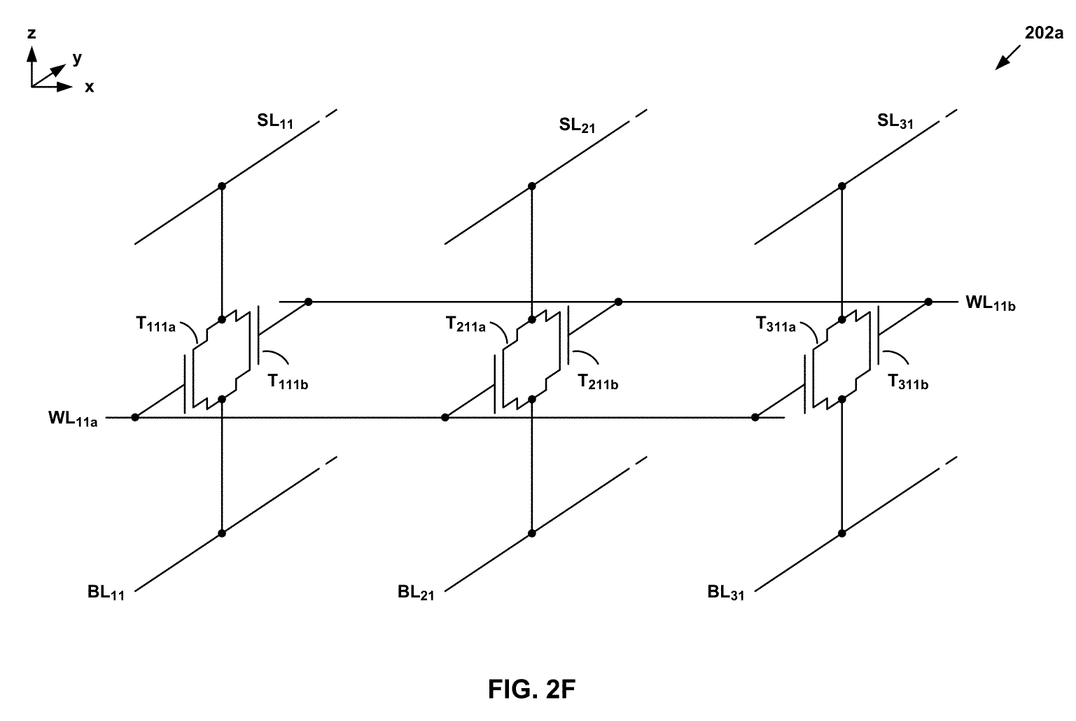

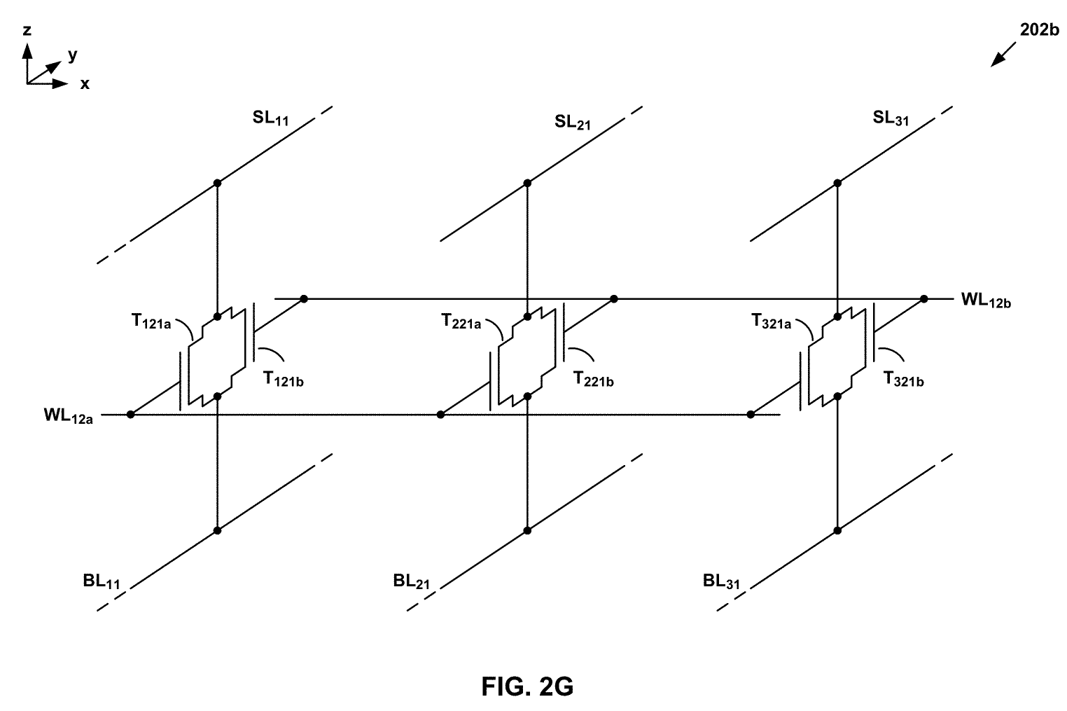

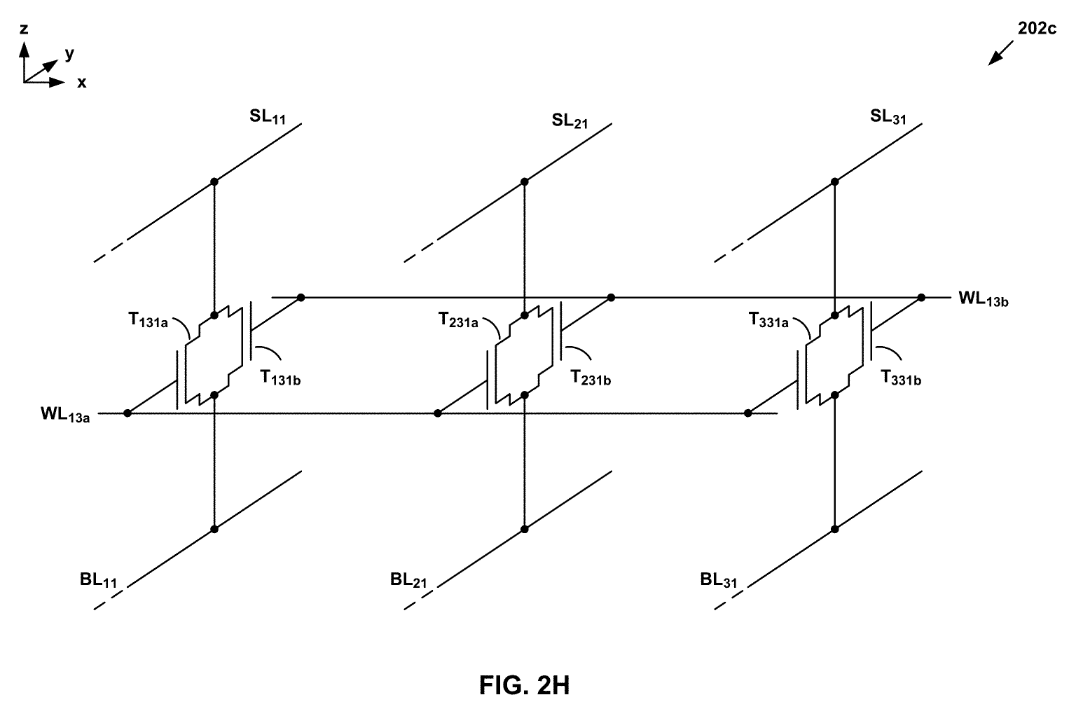

FIG. 2A depicts one embodiment of a portion of a monolithic three-dimensional memory array 200 that includes a first memory level 202, a second memory level 204 positioned above first memory level 202, and a third memory level 206 positioned above second memory level 204. Memory array 200 is one example of an implementation for memory array 150 in FIG. 1E. Memory array 200 includes bit lines BL₁₁-BL₃₂ and source lines SL₁₁-SL₃₂ arranged in a first direction (e.g., an x-direction), and word lines WL₁₁-WL₃₃ are arranged in a second direction (e.g., a y-direction) perpendicular to the first direction. In other embodiments, bit lines BL₁₁-BL₃₂ may be arranged in a first direction (e.g., an x-direction), and source lines WL₁₁-WL₃₂ and word lines WL₁₁-WLWL₃₃ may be arranged in a second direction (e.g., a y-direction) perpendicular to the first direction.

Memory array 200 also includes memory elements T₁₁₁-T₃₃₃, each disposed between a corresponding one of bit lines BL₁₁-BL₃₂ and a corresponding one of source lines SL₁₁-SL₃₂, and each coupled to a corresponding one of word lines WL₁₁-WL₃₃. For example, memory element T₁₁₁ is disposed between bit line BL₁₁ and source line SL₁₁, and is coupled to word line WL₁₁. Likewise, memory element T₂₃₂ is disposed between bit line BL₂₂ and source line SL₂₁, and is coupled to word line WL₂₃.

In an embodiment, each of memory elements T₁₁₁-T₃₃₃ is a ferroelectric memory element, and in particular each of memory elements T₁₁₁-T₃₃₃ includes a ferroelectric field-effect transistor (Fe-FET). Accordingly, each of memory elements T₁₁₁-T₃₃₃ also will be referred to herein as vertical FeFETs T₁₁₁-T₃₃₃. In an embodiment, each of memory elements T₁₁₁-T₃₃₃ includes a Fe-FET and includes no other circuit elements.

FIG. 2B depicts an illustrative electrical characteristic (drain current I_{D} versus gate voltage V_{G}) plot of a FeFET memory element. As illustrated in FIG. 2B, by virtue of applying a positive or negative voltage to the gate electrode of a FeFET memory element, the polarization of the FeFET memory element can be flipped from a first polarization state (e.g., P1) to a second polarization state (e.g., P2). After the gate voltage is removed, the FeFET memory element retains the polarization state. To read a selected FeFET memory element, a read voltage V_{R} (e.g., 0V) is applied to the gate of the selected FeFET memory element, and the drain current of the FeFET memory element is measured. A measured drain current of I_{H} may correspond to a first memory state, whereas a measured drain current of I_{L} may correspond to a second memory state.

Referring again to FIG. 2A, in an embodiment, each of memory elements T₁₁₁-T₃₃₃ includes a vertical Fe-FET that has a ferroelectric gate oxide material. In an embodiment, the ferroelectric gate oxide material includes hafnium oxide. In an embodiment, the ferroelectric gate oxide material includes hafnium oxide doped with one or more of silicon, aluminum, zirconium, yttrium, gadolinium, calcium, cerium, dysprosium, erbium, germanium, scandium, and tin. In an embodiment, the hafnium oxide is doped with silicon with a concentration of about 2 to about 5 atomic %. In another embodiment, the ferroelectric gate oxide material includes hafnium zirconium oxide, where the ratio of hafnium to zirconium atomic concentrations is 1 to 1. In an embodiment, the doped hafnium oxide is in a crystalline or polycrystalline morphology. The crystal grains of the doped hafnium oxide are switched, either separately or as an ensemble, between a first polarization state (e.g., P1) to a second polarization state (e.g., P2).

In an embodiment, and as described in more detail below, each of memory elements T₁₁₁-T₃₃₃ may be configured as a single memory cell including a dual-gated vertical Fe-FET, or may be configured as two independent memory cells, each including a single-gated vertical Fe-FET.

FIGS. 2C-2E depict an embodiment of first memory level 202, second memory level 204, and third memory level 206, respectively, of memory array 200 of FIG. 2A. Each of memory elements T₁₁₁-T₃₃₃ includes a vertical Fe-FET having a first electrode (e.g., a drain/source electrode) coupled to one of bit lines BL₁₁-BL₃₂, a second electrode (e.g., a source/drain electrode) coupled to one of source lines SL₁₁-SL₃₂, and a third electrode (e.g., a gate electrode) coupled to one of word lines WL₁₁-WL₃₃. Persons of ordinary skill in the art will understand that source lines SL₁₁-SL₃₂ alternatively may be disposed above bit lines BL₁₁-BL₃₂, with each memory element T₁₁₁-T₃₃₃ coupled between one of bit lines BL₁₁-BL₃₂ and one of source lines SL₁₁-SL₃₂.

To avoid overcrowding the drawing, memory elements T₁₁₁-T₃₃₃ in FIGS. 2C-2E are depicted as “flattened” Fe-FETs rather than as vertical transistors. Each of word lines WL₁₁-WL₃₃ includes a first word line and a second word line (e.g., word line WL₁₁ includes a first word line WL₁₁ₐ and a second word line WL_{11b}) that are coupled to a corresponding first gate electrode and second gate electrode, respectively, of memory elements T₁₁₁-T₃₃₃.

For example, memory element T₂₂₁ (FIG. 2C) has a first electrode (e.g., a drain/source electrode) coupled to bit line BL₂₁, a second electrode (e.g., a source/drain electrode) coupled to source line SL₂₁, a first gate electrode coupled to first word line WL₁₂ₐ and a second gate electrode coupled to second word line WL_{12b}. Likewise, memory element T₃₃₂ (FIG. 2D) has a first electrode (e.g., a drain/source electrode) coupled to bit line BL₃₂, a second electrode (e.g., a source/drain electrode) coupled to word line WL₃₁, a first gate electrode coupled to first word line WL₂₃ₐ and a second gate electrode coupled to second word line WL_{23b}. Similarly, memory element T₁₃₃ (FIG. 2E) has a first electrode (e.g., a drain/source electrode) coupled to bit line BL₁₂, a second electrode (e.g., a source/drain electrode) coupled to source line SL₁₂, a first gate electrode coupled to first word line WL₃₃ₐ and a second gate electrode coupled to second word line WL_{33b}.

In the embodiment depicted in FIGS. 2C-2E, the first gate electrode and the second gate electrode of each of memory elements T₁₁₁-T₃₃₃ are disposed on opposite sides of the vertical Fe-FET. The first gate electrode may be used to selectively induce a first conductive channel between the first electrode and the second electrode of the vertical Fe-FET, and set the polarization state (P1/P2) of a first portion of the vertical FeFET, and the second gate electrode may be used to selectively induce a second conductive channel between the first electrode and the second electrode of the vertical Fe-FET, and set the polarization state (P1/P2) of a second portion of the vertical FeFET.

The first gate electrode and the second gate electrode of each of memory elements T₁₁₁-T₃₃₃ are independent control terminals that may be used to set polarization states (P1/P2) of the first portion and the second portion, respectively, of the vertical Fe-FET. In an embodiment, each of memory elements T₁₁₁-T₃₃₃ may be configured as a single memory cell that includes a dual-gated vertical Fe-FET. In such an embodiment, the first word line and second word line coupled to the first gate electrode and the second gate electrode, respectively, of a memory element are coupled together and collectively set the polarization states (P1/P2) of the first and second portions of the vertical Fe-FET.

In another embodiment, each of memory elements T₁₁₁-T₃₃₃ may be configured as two independent memory cells, each including a single-gated vertical Fe-FET. In such an embodiment, the first word line and second word line coupled to the first gate electrode and the second gate electrode, respectively, of a memory element are not coupled together. Instead, the first word line may be used to individually set polarization states (P1/P2) of a first portion of the vertical FeFET, and the second word line may be used to individually set polarization states (P1/P2) of the second portion of the vertical Fe-FET. In this regard, each dual-gated vertical Fe-FET may be considered as two parallel-coupled single-gated vertical Fe-FETs, with each single-gated vertical Fe-FET comprising a memory cell.

For example, FIGS. 2F-2H, depict an embodiment of a first row 202a of memory elements T₁₁₁, T₂₁₁ and T₃₁₁, a second row 202b of memory elements T₁₂₁, T₂₂₁ and T₃₂₁, and a third row 202c of memory elements T₁₃₁, T₂₃₁ and T₃₃₁, respectively, of first memory level 202 of FIG. 2C. In particular, each of memory elements T₁₁₁-T₃₃₁ includes a two memory cells: a first memory cell including a first vertical Fe-FET coupled in parallel with a second memory cell including a second vertical Fe-FET, with the first gate electrode controlling the first vertical Fe-FET and the second gate electrode controlling the second vertical Fe-FET.

Referring to FIG. 2F, memory element T₁₁₁ includes a first memory cell T₁₁₁ₐ including a first vertical Fe-FET coupled in parallel with a second memory cell T_{111b} including a second vertical Fe-FET, both coupled between bit line BL₁₁ and source line SL₁₁, memory element T₂₁₁ includes a first memory cell T₂₁₁ₐ including a first vertical Fe-FET coupled in parallel with a second memory cell T_{211b} including a second vertical Fe-FET, both coupled between bit line BL₂₁ and source line SL₂₁, and memory element T₃₁₁ includes a first memory cell T₃₁₁ₐ including a first vertical Fe-FET coupled in parallel with a second memory cell T_{311b} including a second vertical Fe-FET, both coupled between bit line BL₃₁ and source line SL₃₁. First memory cells T₁₁₁ₐ, T₂₁₁ₐ, and T₃₁₁ₐ each have first gate electrodes coupled to first word line WL₁₁ₐ, and second memory cells T_{11b}, T_{211b}, and T_{311b} each have second gate electrodes coupled to second word line WL_{11b}.

Referring to FIG. 2G, memory element T₁₂₁ includes a first memory cell T₁₂₁ₐ including a first vertical Fe-FET coupled in parallel with a second memory cell T_{121b} including a second vertical Fe-FET, both coupled between bit line BL₁₁ and source line SL₁₁, memory element T₂₂₁ includes a first memory cell T₂₂₁ₐ including a first vertical Fe-FET coupled in parallel with a second memory cell T_{221b} including a second vertical Fe-FET, both coupled between bit line BL₂₁ and source line SL₂₁, and memory element T₃₂₁ includes a first memory cell T₃₂₁ₐ including a first vertical Fe-FET coupled in parallel with a second memory cell T_{321b} including a second vertical Fe-FET, both coupled between bit line BL₃₁ and source line SL₃₁. First memory cells T₁₂₁ₐ, T₂₂₁ₐ, and T₃₂₁ₐ each have first gate electrodes coupled to first word line WL₁₂ₐ, and second memory cells T_{121b}, T_{221b}, and T_{321b} each have second gate electrodes coupled to second word line WL_{12b}.

Referring to FIG. 2H, memory element T₁₃₁ includes a first memory cell T₁₃₁ₐ including a first vertical Fe-FET coupled in parallel with a second memory cell T_{131b} including a second vertical Fe-FET, both coupled between bit line BL₁₁ and source line SL₁₁, memory element T₂₃₁ includes a first memory cell T₂₃₁ₐ including a first vertical Fe-FET coupled in parallel with a second memory cell T_{231b} including a second vertical Fe-FET, both coupled between bit line BL₂₁ and source line SL₂₁, and memory element T₃₃₁ includes a first memory cell T₃₃₁ₐ including a first vertical Fe-FET coupled in parallel with a second memory cell T_{331b} including a second vertical Fe-FET, both coupled between bit line BL₃₁ and source line SL₃₁. First memory cells T₁₃₁ₐ, T₂₃₁ₐ, and T₃₃₁ₐ each have first gate electrodes coupled to first word line WL₁₃ₐ, and second memory cells T_{131b}, T_{231b}, and T_{331b} each have second gate electrodes coupled to second word line WL_{13b}.

In the embodiments described above and depicted in FIGS. 2C-2H, each of memory elements T₁₁₁-T₃₃₃ may be a ferroelectric memory element, and in particular may include vertical Fe-FETs that have a gate oxide including one or more of hafnium oxide and hafnium zirconium oxide. In an embodiment, the gate oxide includes hafnium oxide doped with one or more of silicon, aluminum, zirconium, yttrium, gadolinium, calcium, cerium, dysprosium, erbium, germanium, scandium, and tin.

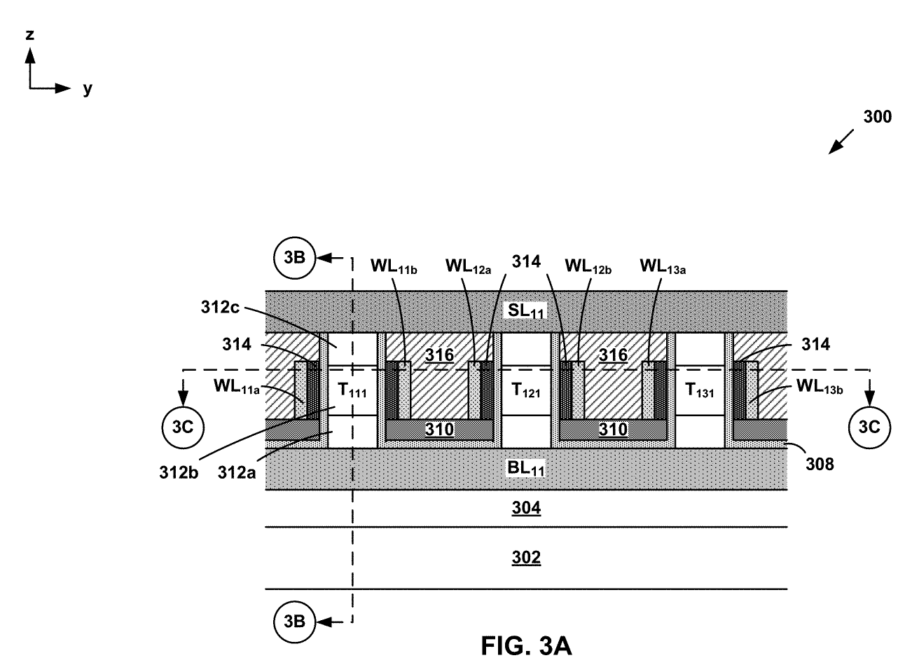

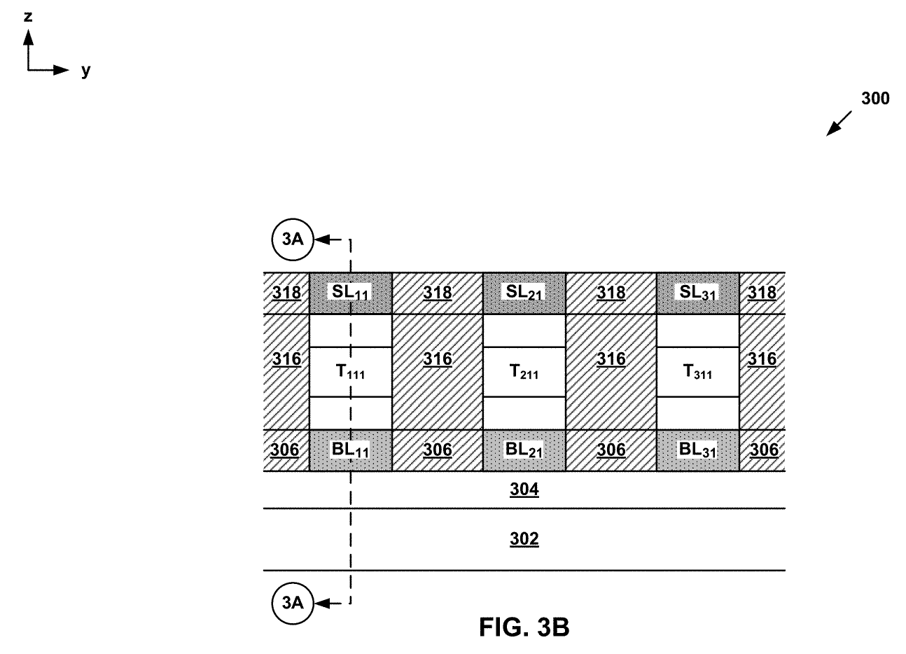

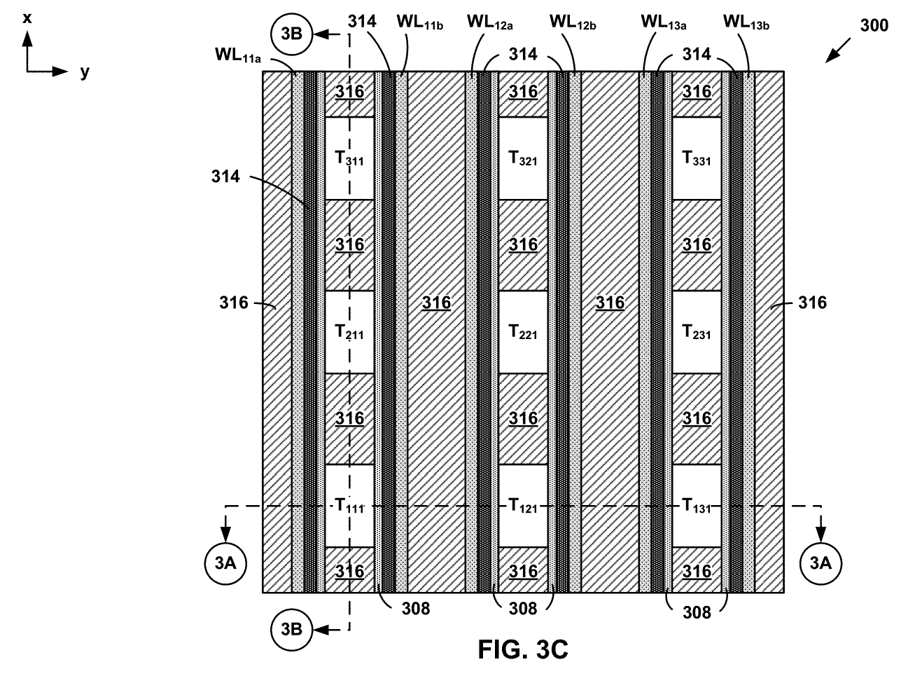

FIGS. 3A-3C depict various views of an embodiment of a portion of a monolithic three-dimensional memory array 300 that includes vertical Fe-FETs that have a gate oxide including hafnium oxide. The physical structure depicted in FIGS. 3A-3C may include one implementation for a portion of the monolithic three-dimensional memory array 200 depicted in FIG. 2A.

Monolithic three-dimensional memory array 300 includes bit lines BL₁₁-BL₃₁ and source lines SL₁₁-SL₃₁ arranged in a first direction (e.g., an x-direction), and word lines WL₁₁ₐ-WL_{13b} arranged in a second direction (e.g., a y-direction) perpendicular to the first direction. Source lines SL₁₁-SL₃₁ are disposed above bit lines BL₁₁-BL₃₁, and each have a long axis in the second direction (e.g., y-direction). Persons of ordinary skill in the art will understand that monolithic three-dimensional memory arrays, such as monolithic three-dimensional memory array 300 may include more or fewer than three source lines, three bit lines, and six word lines.

In an embodiment, bit lines BL₁₁, BL₂₁, BL₃₁ are disposed above a substrate 302, such as a silicon, germanium, silicon-germanium, undoped, doped, bulk, silicon-on-insulator (“SOI”) or other substrate with or without additional circuitry. In an embodiment, an isolation layer 304, such as a layer of silicon dioxide, silicon nitride, silicon oxynitride or any other suitable insulating layer, is formed above substrate 302.

In an embodiment, a first dielectric material layer 306 (e.g., silicon dioxide) is formed above isolation layer 304. Bit lines BL₁₁, BL₂₁, BL₃₁ are disposed above isolation layer 304 and are separated by first dielectric material layer 306. Bit lines BL₁₁, BL₂₁, BL₃₁ are formed of a conductive material (e.g., tungsten) and may include an adhesion layer (not shown) disposed on an outer surface of each bit line B_{L11}, BL₂₁, BL₃₁.

Memory elements (vertical Fe-FETs) T₁₁₁-T₃₃₁ are formed above bit lines BL₁₁, BL₂₁, BL₃₁, and each has a first electrode (e.g., a drain/source electrode) disposed on and coupled to one of bit lines BL₁₁, BL₂₁, BL₃₁, a second electrode (e.g., a source/drain electrode) coupled to one of source lines SL₁₁, SL₂₁, SL₃₁, a first gate electrode coupled to one of word lines WL₁₁ₐ, WL₁₂ₐ, WL₁₃ₐ, and a second gate electrode coupled to one of word lines WL_{11b}, WL_{12b}, WL_{13b}. For each vertical Fe-FET T₁₁₁-T₃₃₁, the first gate electrode and the second gate electrode are disposed on opposite sides of the vertical Fe-FET.

Each vertical Fe-FETs T₁₁₁-T₃₃₁ includes a vertical semiconductor pillar that includes a first region 312a (e.g., n+ polysilicon), a second region 312b (e.g., p polysilicon) and a third region 312c (e.g., n+ polysilicon) to form drain/source, body, and source/drain regions, respectively, of a vertical FET. In an embodiment, the vertical semiconductor pillar has a rectangular shape, although other pillar shapes may be used.

Word lines WL₁₁ₐ-WL_{13b} are formed of a conductive material (e.g., titanium nitride) and are disposed above and separated from bit lines BL₁₁, BL₂₁, BL₃₁ by a second dielectric 308 (e.g., SiON) and optionally also may be separated from BL₁₁, BL₂₁, BL₃₁ by a spacer dielectric 310 (e.g., SiO₂). A ferroelectric gate oxide 314 (e.g., silicon-doped HfO₂) is disposed between word lines WL₁₁ₐ-WL_{13b} and sidewalls of first region 312a, second region 312b and third region 312c of vertical Fe-FETs T₁₁₁-T₃₃₁. Second dielectric 308 may be disposed between gate oxide 314 and sidewalls of first region 312a, second region 312b and third region 312c of vertical Fe-FETs T₁₁₁-T₃₃₁.

In an embodiment, the first gate electrode and second gate electrode of vertical Fe-FETs T₁₁₁, T₂₁₁, T₃₁₁ are coupled to word lines WL₁₁ₐ and WL_{11b}, respectively, the first gate electrode and second gate electrode of vertical Fe-FETs T₁₂₁, T₂₂₁, T₃₂₁ are coupled to word lines WL₁₂ₐ and WL_{12b}, respectively, and the first gate electrode and second gate electrode of vertical Fe-FETs T₁₃₁, T₂₃₁, T₃₃₁ are coupled to word lines WL₁₃ₐ and WL_{13b}, respectively. A third dielectric 316 (e.g., SiO₂) is disposed between and electrically isolates vertical Fe-FETs T₁₁₁-T₃₃₁.

Source lines SL₁₁, SL₂₁, SL₃₁ are disposed above and are coupled to third regions 312c of vertical Fe-FETs T₁₁₁-T₃₃₁, and are separated by fourth dielectric material layer 318. Source lines SL₁₁, SL₂₁, SL₃₁ are formed of a conductive material (e.g., tungsten) and may include an adhesion layer (not shown) disposed on an outer surface of each source line SL₁₁, SL₂₁, SL₃₁.

Without wanting to be bound by any particular theory, it is believed that monolithic three-dimensional memory array 300 of FIGS. 3A-3C may be used to form a compact memory array including vertical FeFETs. Each vertical FeFET has two gate electrodes that may be controlled collectively or separately. In addition, a stackable memory may be achieved by vertically stacking layers of monolithic three-dimensional memory arrays, such as monolithic three-dimensional memory array 300 of FIGS. 3A-3C.

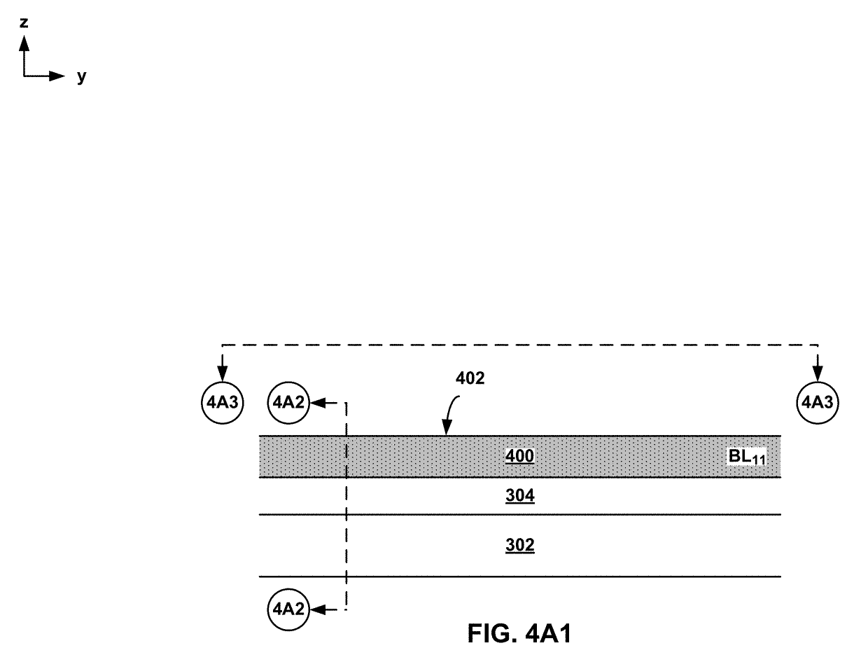

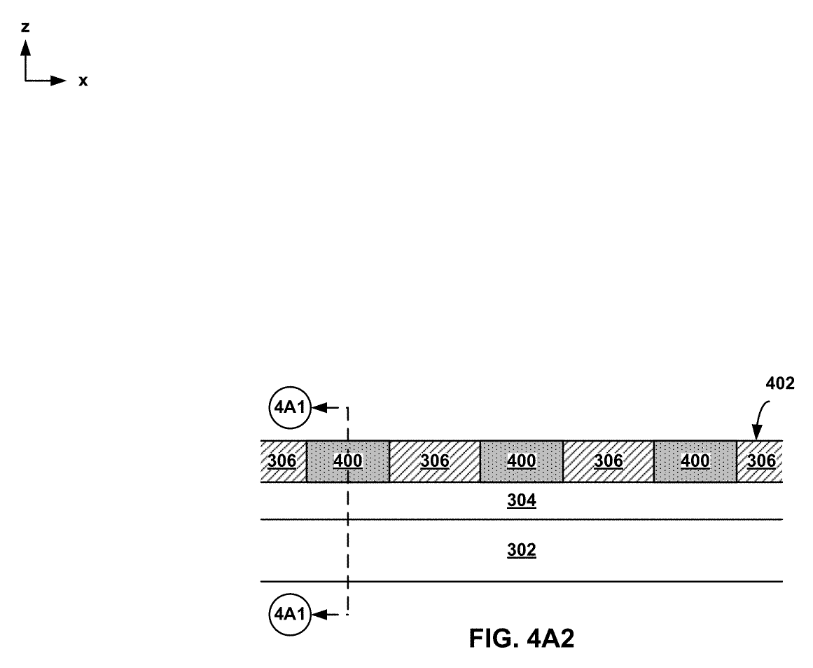

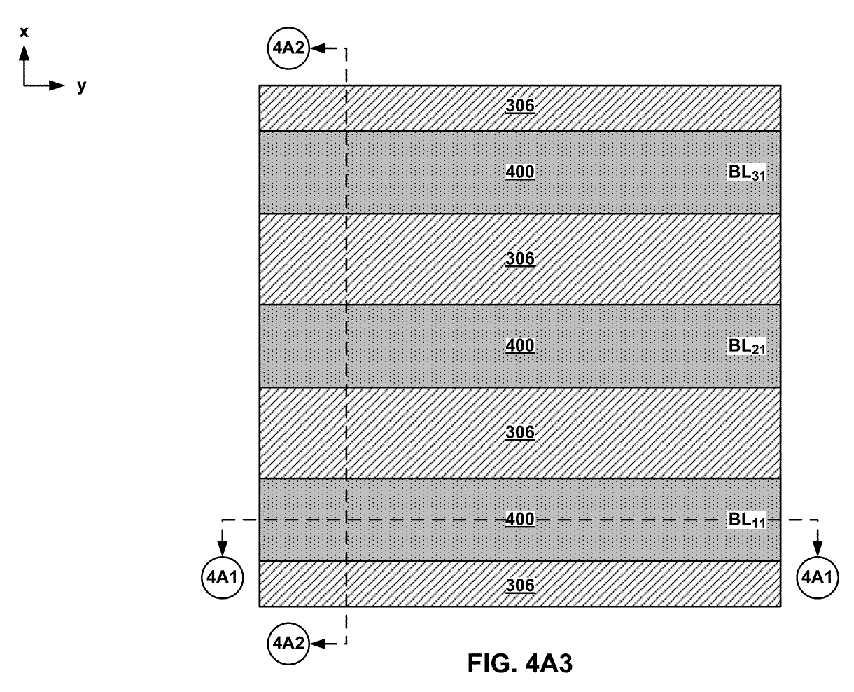

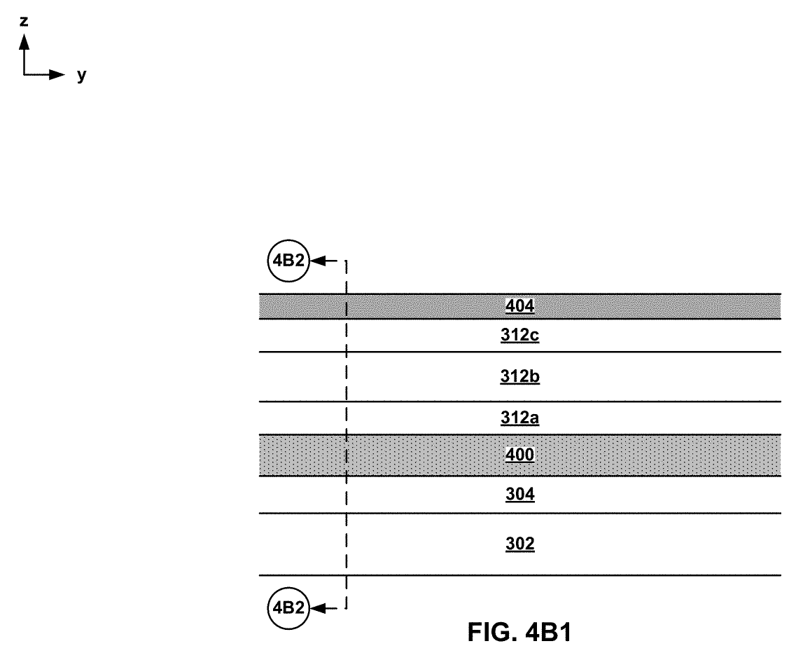

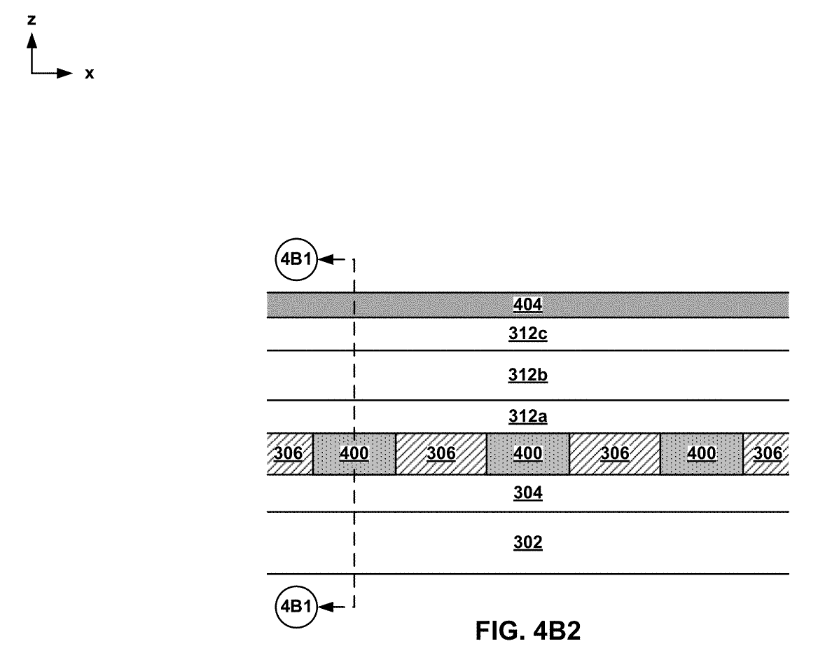

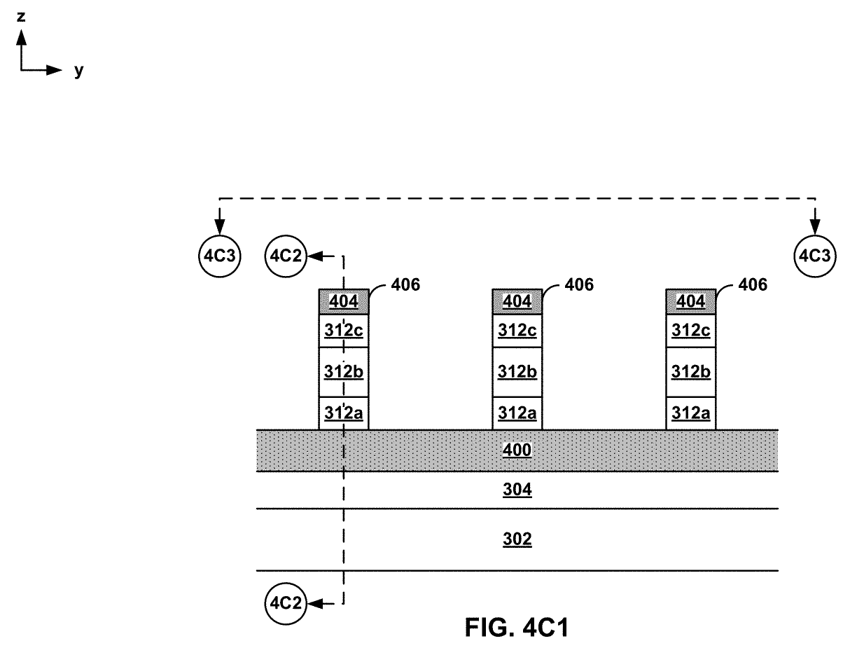

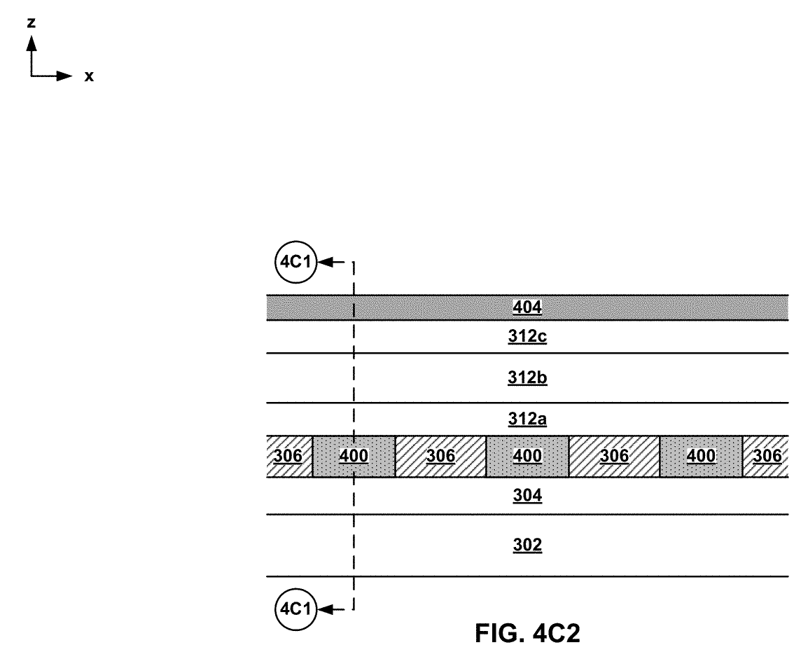

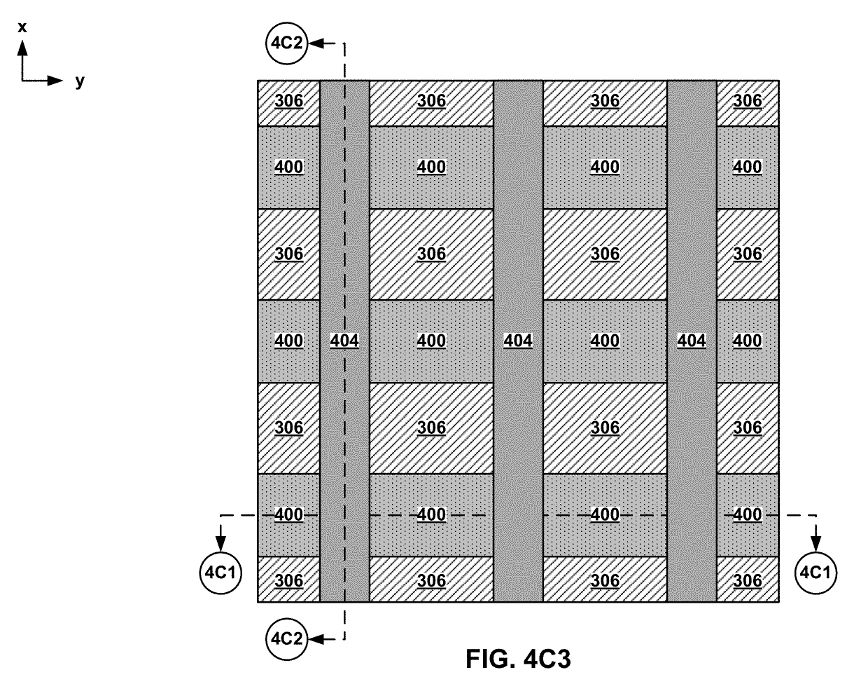

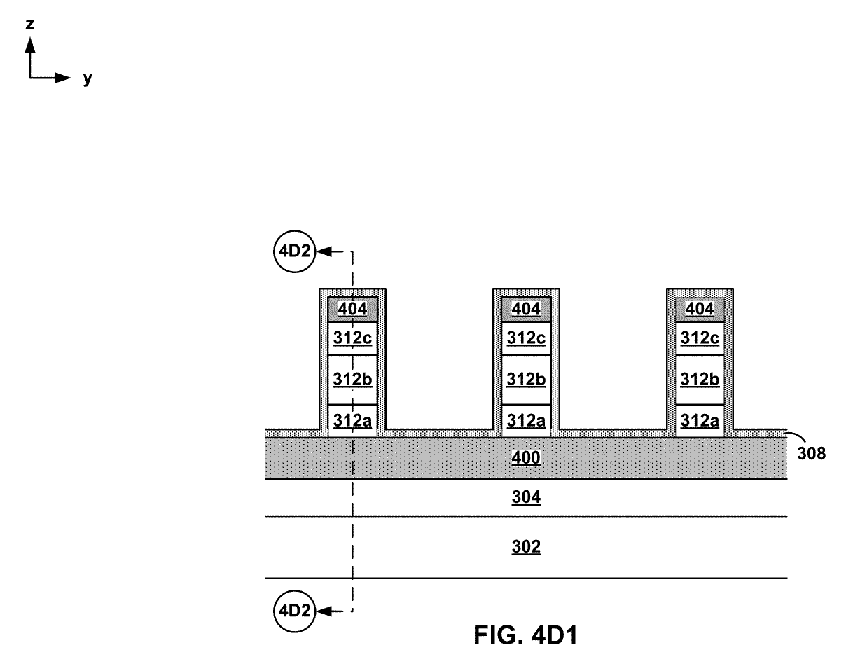

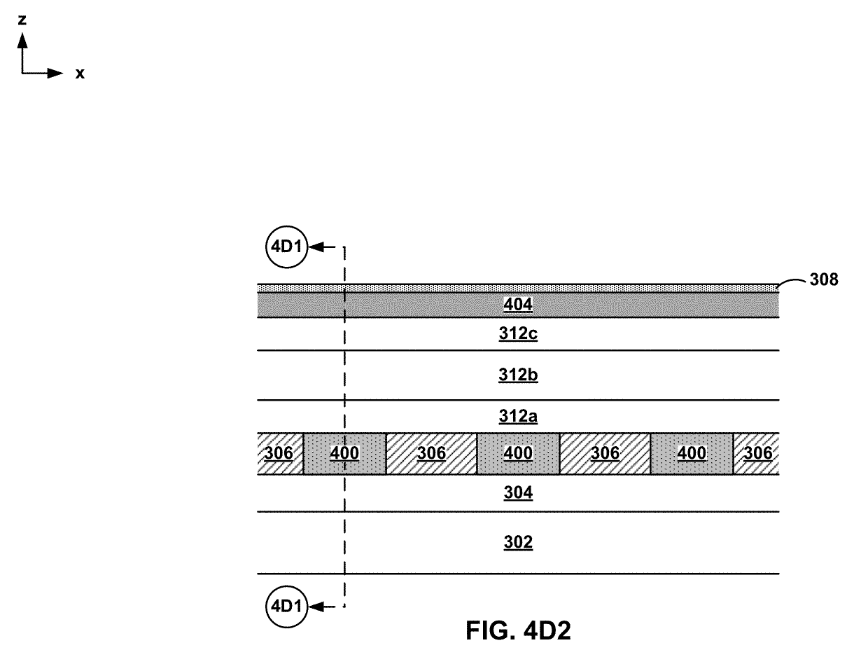

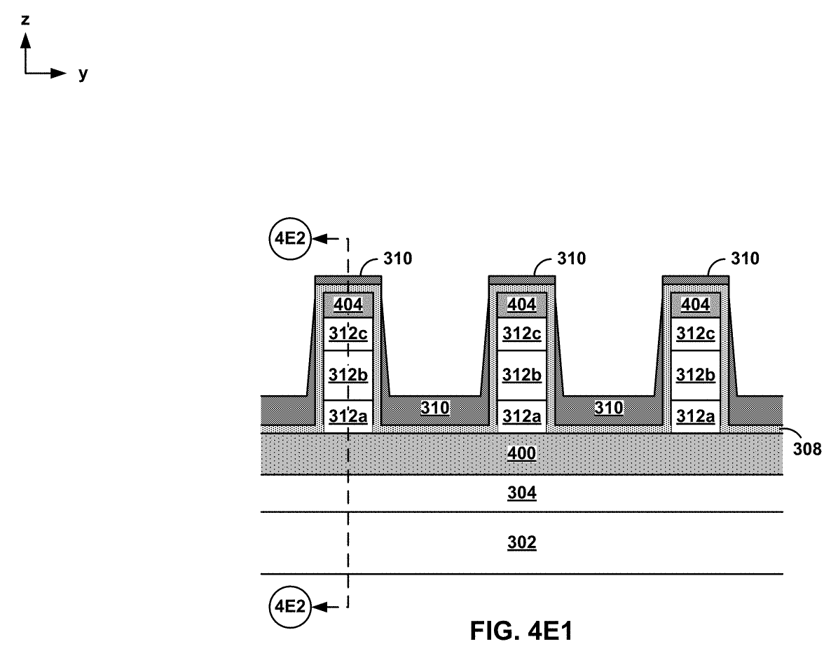

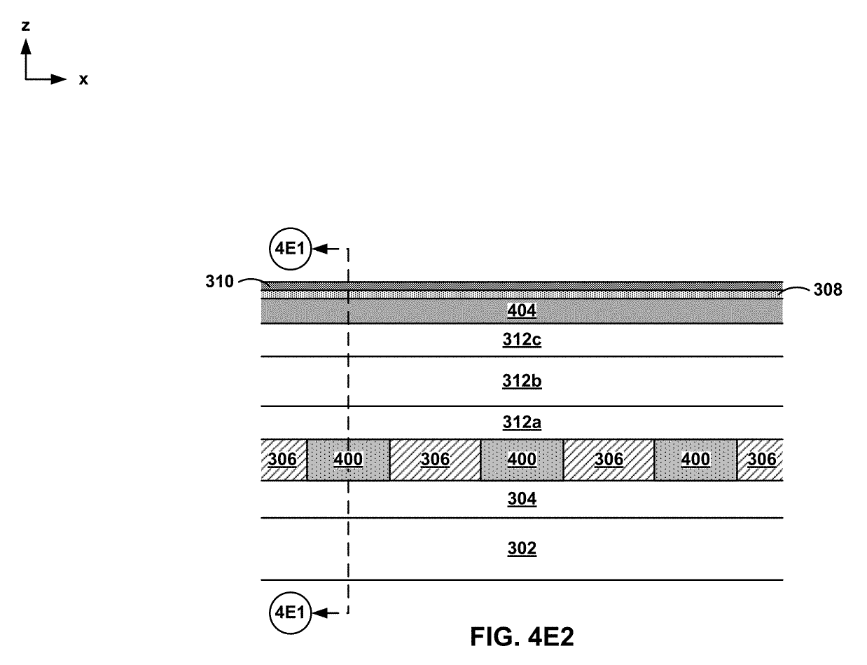

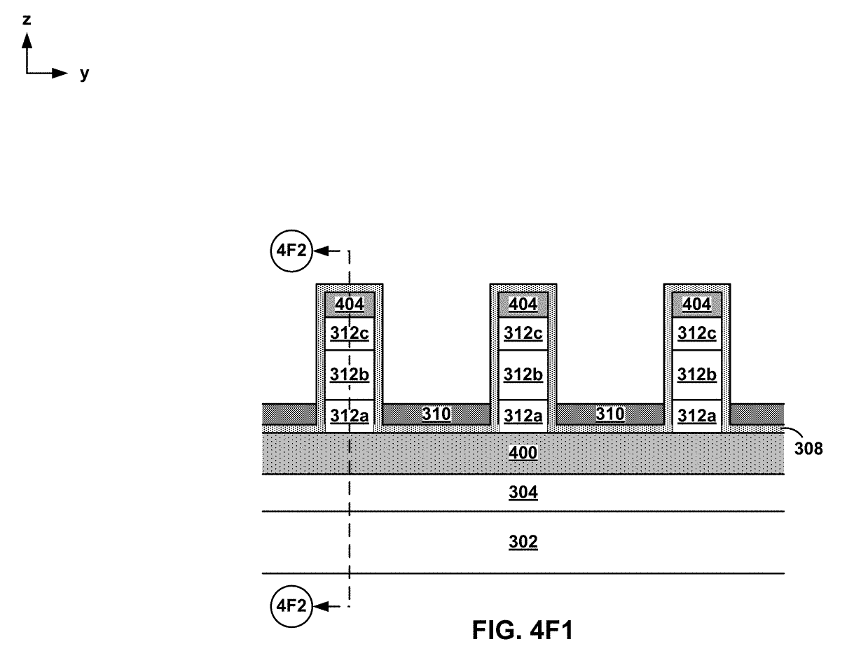

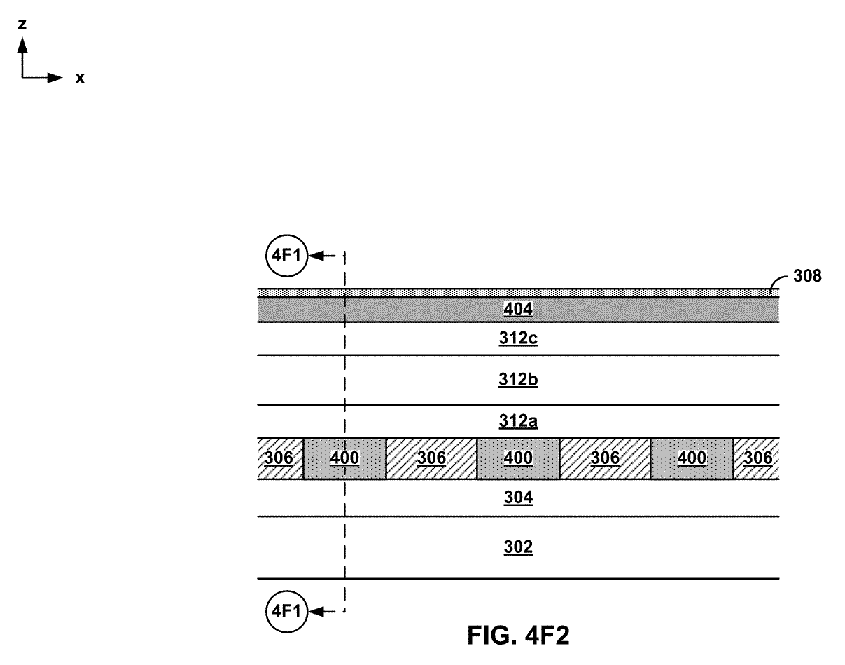

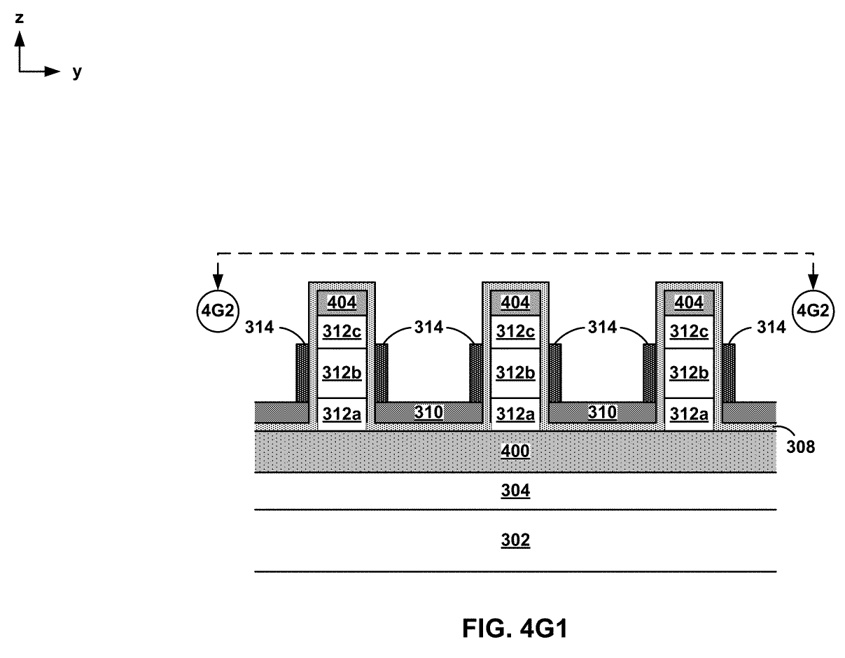

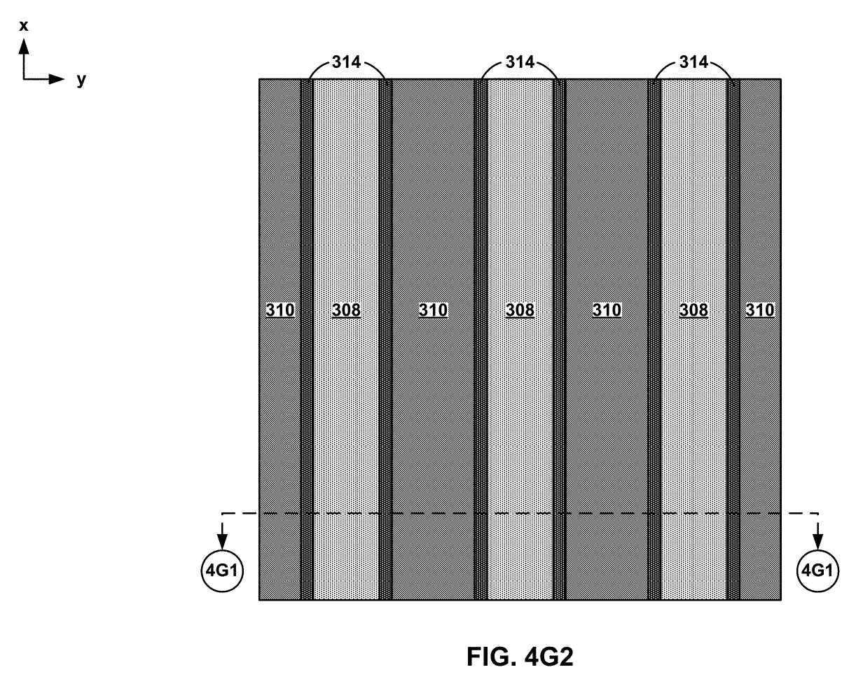

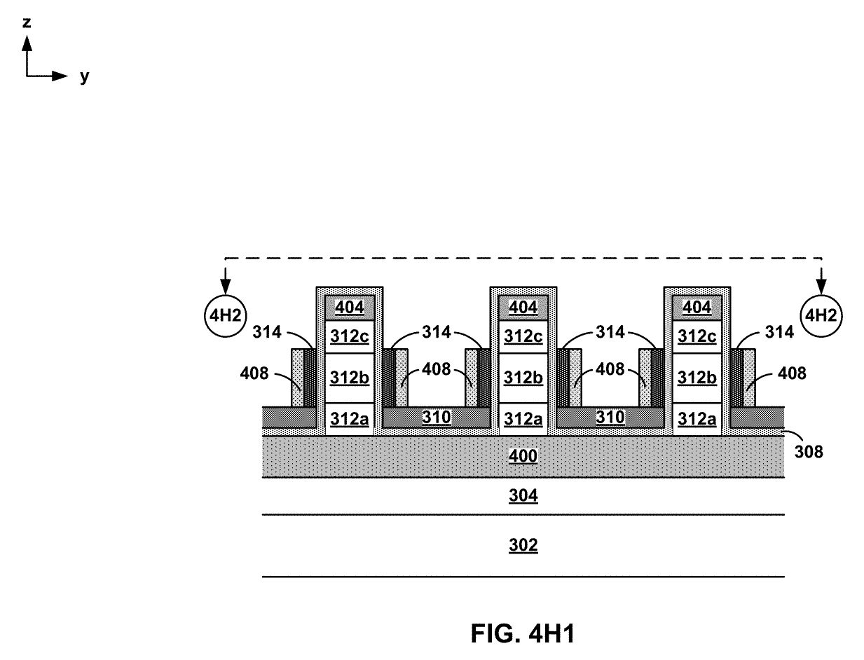

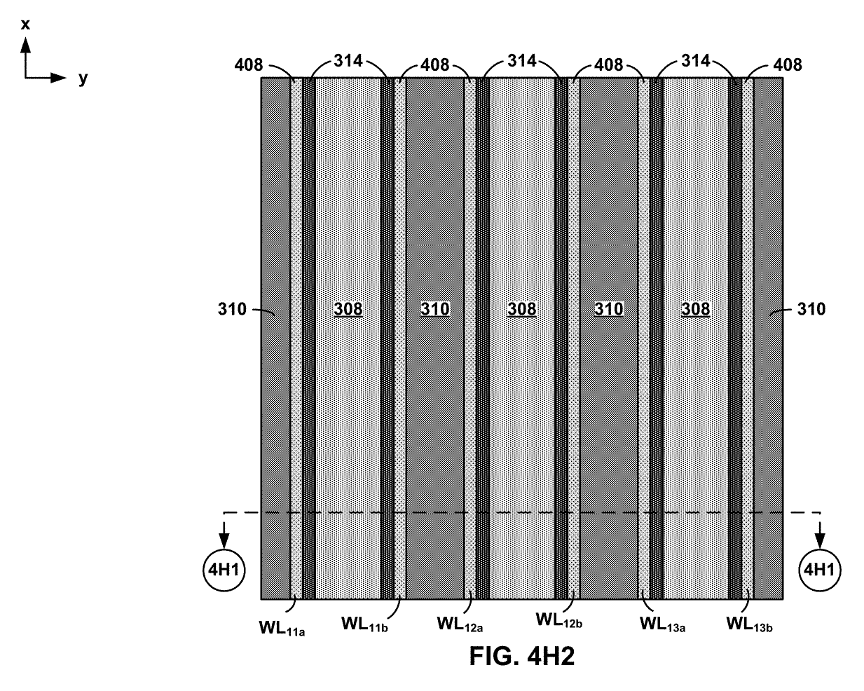

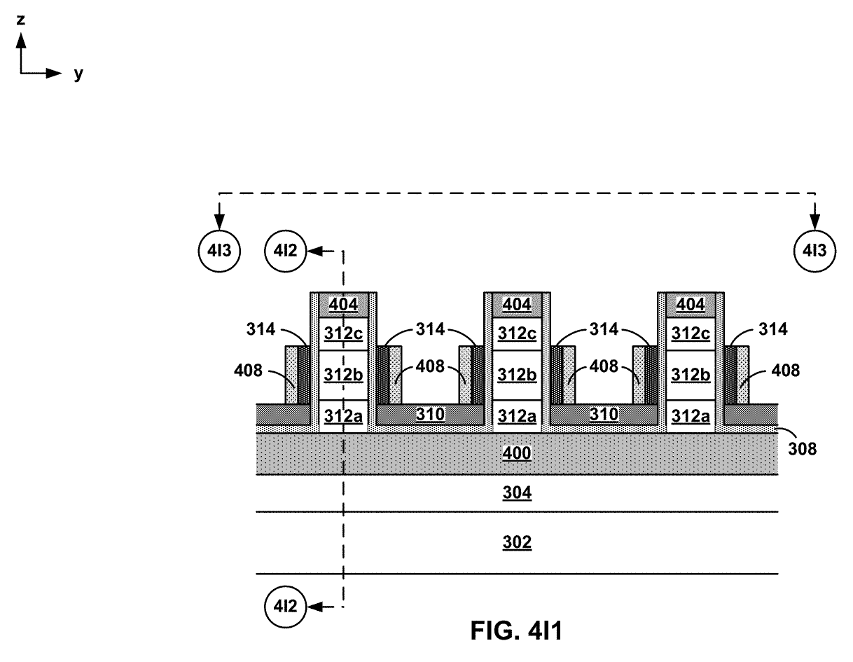

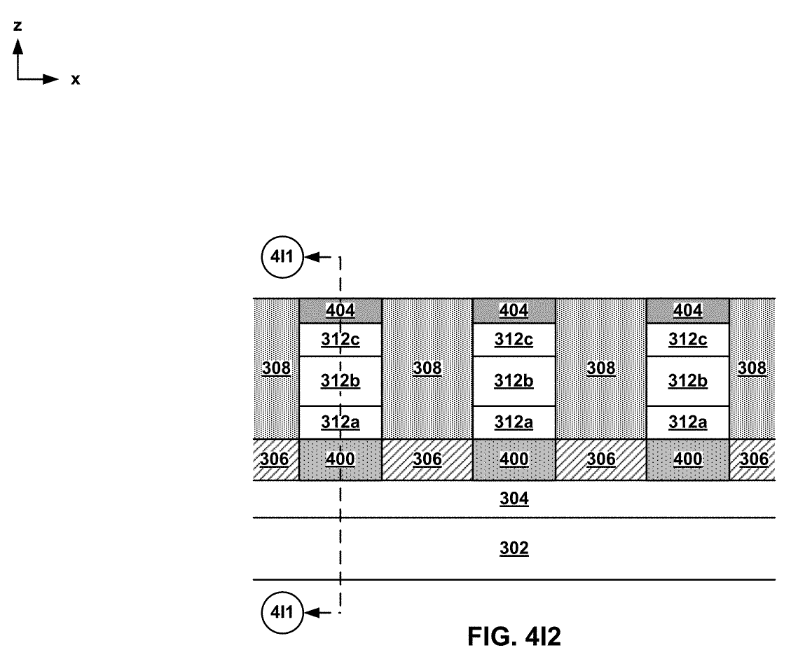

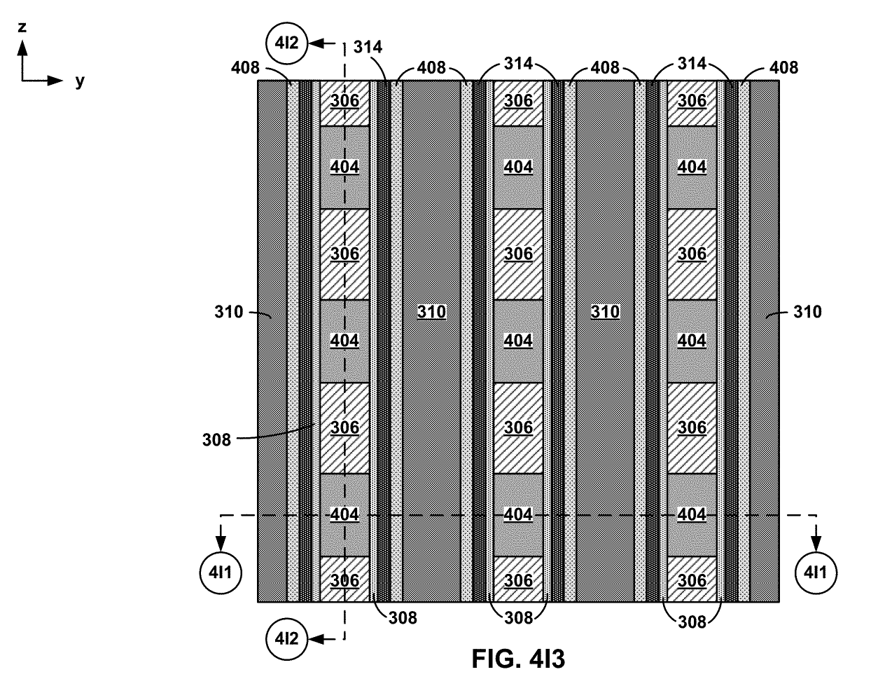

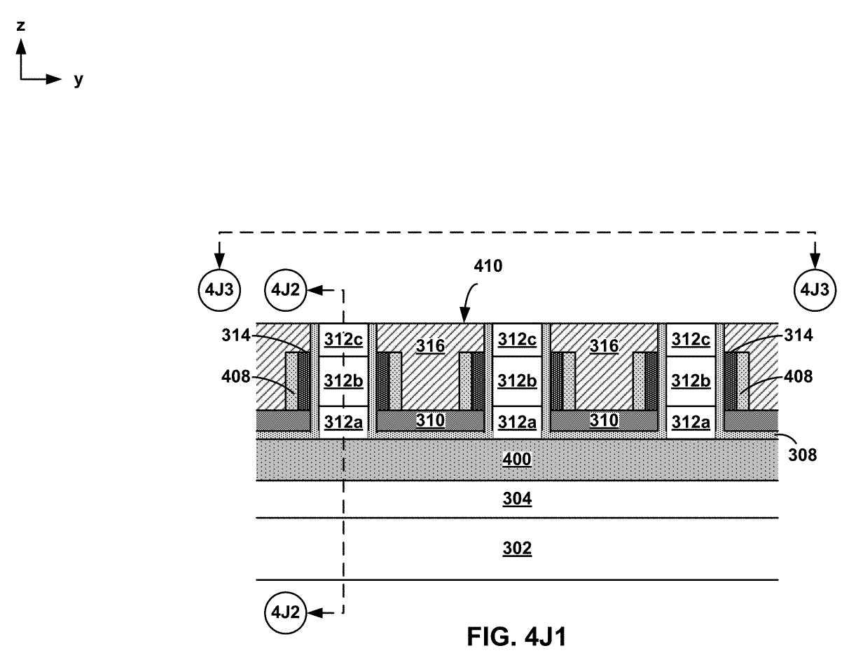

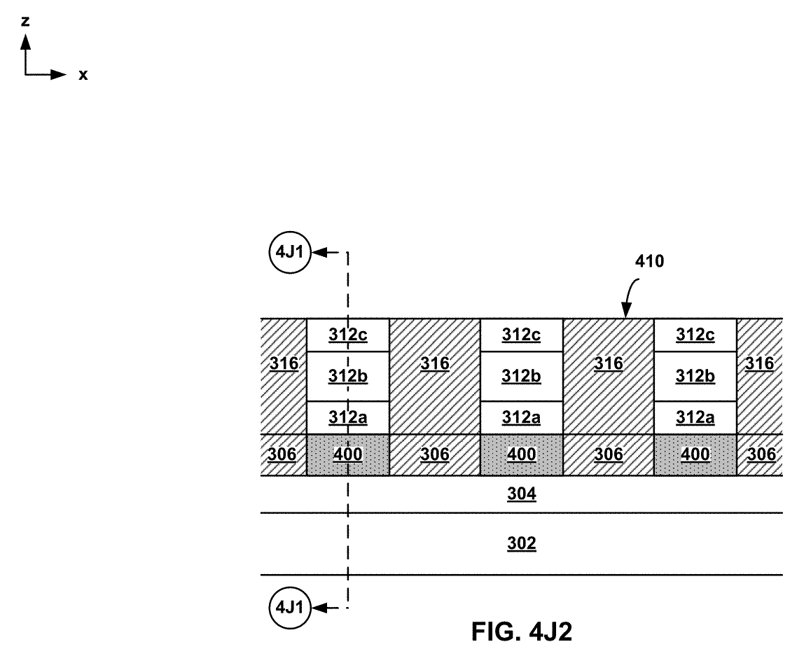

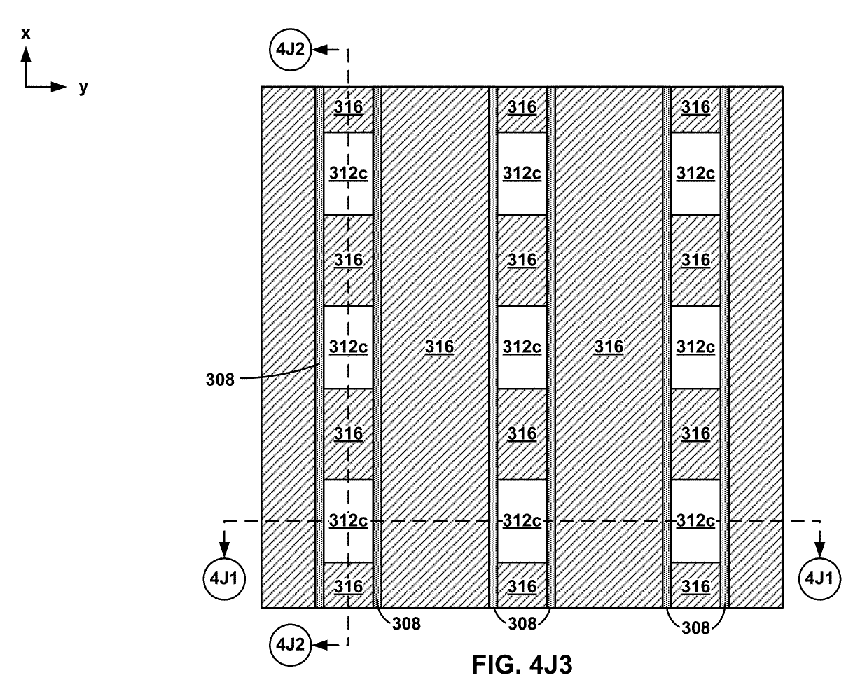

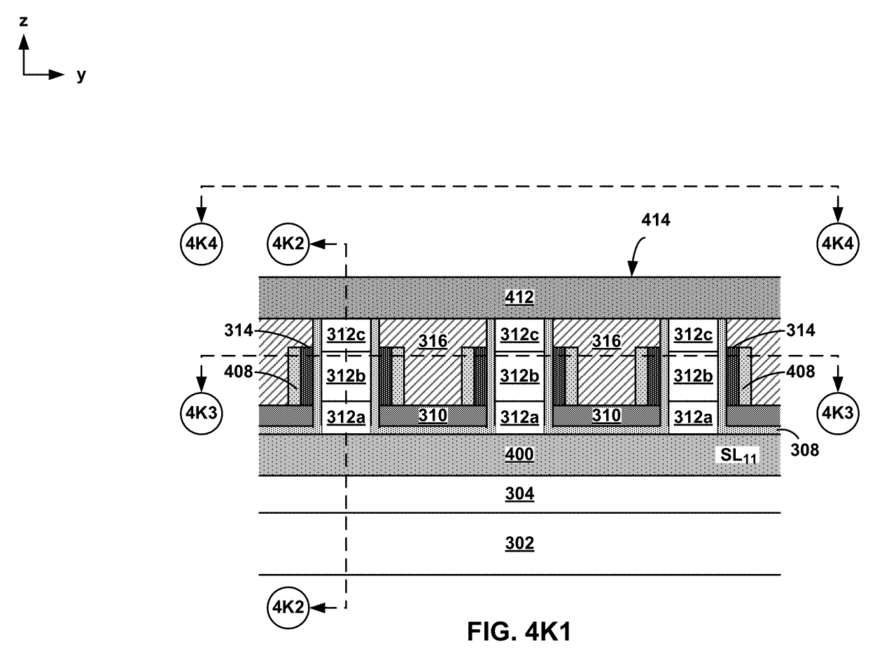

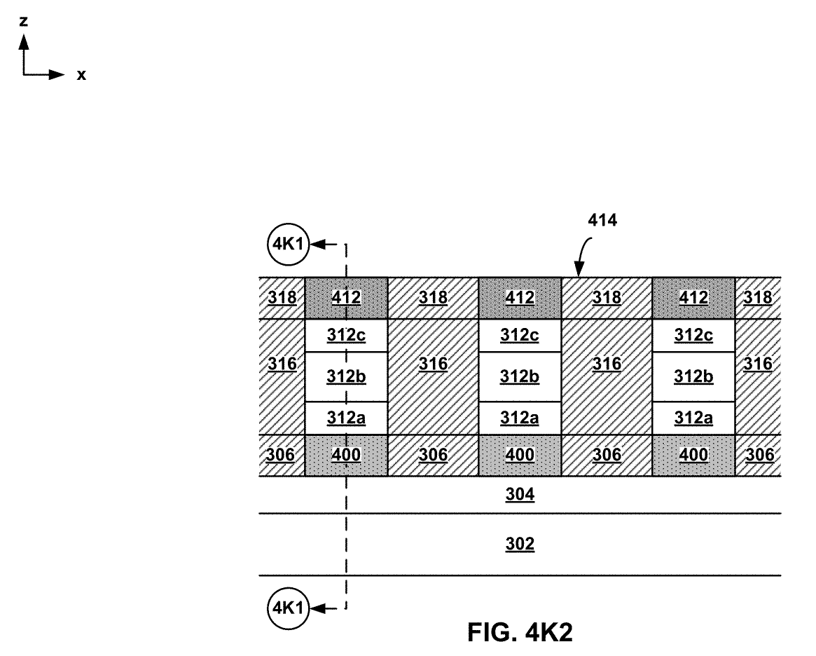

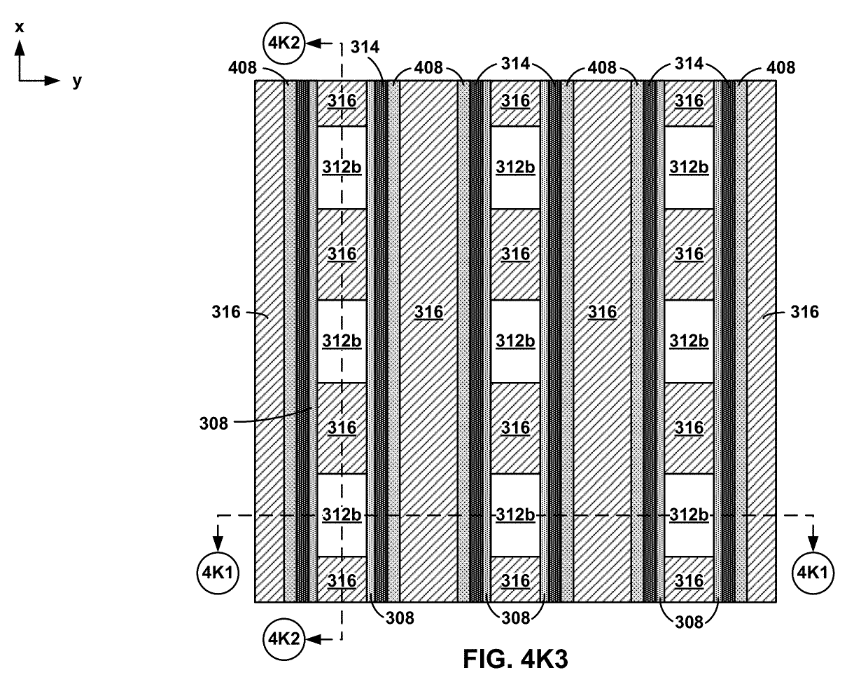

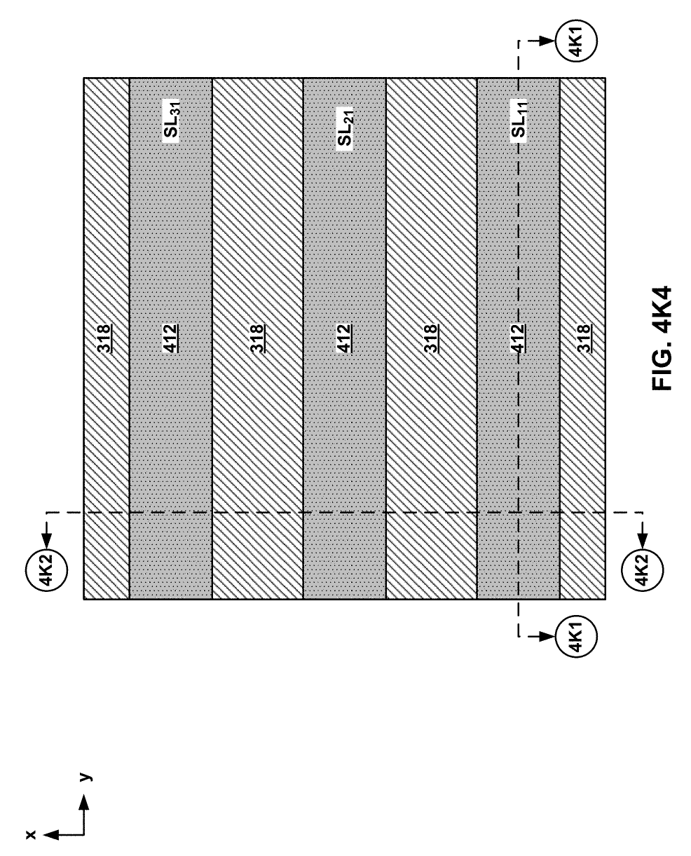

Referring now to FIGS. 4A1-4K4, an example method of forming a portion of a monolithic three-dimensional memory array, such as monolithic three-dimensional array 300 of FIGS. 3A-3C, is described.

With reference to FIGS. 4A1-4A3, substrate 302 is shown as having already undergone several processing steps. Substrate 302 may be any suitable substrate such as a silicon, germanium, silicon-germanium, undoped, doped, bulk, silicon-on-insulator (“SOI”) or other substrate with or without additional circuitry. For example, substrate 302 may include one or more n-well or p-well regions (not shown). Isolation layer 304 is formed above substrate 302. In some embodiments, isolation layer 304 may be a layer of silicon dioxide, silicon nitride, silicon oxynitride or any other suitable insulating layer.

Following formation of isolation layer 304, a conductive material layer 400 is deposited over isolation layer 304. Conductive material layer 400 may include any suitable conductive material such as tungsten or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive material layer 400 may be between about 20 and about 250 nm of tungsten. Other conductive material layers and/or thicknesses may be used. In some embodiments, an adhesion layer (not shown), such as titanium nitride or other similar adhesion layer material, may be disposed between isolation layer 304 and conductive material layer 400, and/or between conductive material layer 400 and subsequent material layers.

Persons of ordinary skill in the art will understand that adhesion layers may be formed by PVD or another method on conductive material layers. For example, adhesion layers may be between about 2 and about 50 nm, and in some embodiments about 10 nm, of titanium nitride or another suitable adhesion layer such as tantalum nitride, tungsten nitride, tungsten, molybdenum, combinations of one or more adhesion layers, or the like. Other adhesion layer materials and/or thicknesses may be employed.

Following formation of conductive material layer 400, conductive material layer 400 is patterned and etched. For example, conductive material layer 400 may be patterned and etched using conventional lithography techniques, with a soft or hard mask, and wet or dry etch processing. In at least one embodiment, conductive material layer 400 is patterned and etched to form bit lines BL₁₁, BL₂₁, BL₃₁. Example widths for bit lines BL₁₁, BL₂₁, BL₃₁ and/or spacings between bit lines BL₁₁, BL₂₁, BL₃₁ range between about 38 nm and about 100 nm, although other conductor widths and/or spacings may be used.

After bit lines BL₁₁, BL₂₁, BL₃₁ have been formed, a first dielectric material layer 306 is formed over substrate 302 to fill the voids between bit lines B_{L11}, BL₂₁, BL₃₁. For example, approximately 300-700 nm of silicon dioxide may be deposited on the substrate 302 and planarized using chemical mechanical polishing or an etchback process to form a planar surface 402. Other dielectric materials such as silicon nitride, silicon oxynitride, low K dielectrics, etc., and/or other dielectric material layer thicknesses may be used. Example low K dielectrics include carbon doped oxides, silicon carbon layers, or the like.

In other embodiments, bit lines BL₁₁, BL₂₁, BL₃₁ may be formed using a damascene process in which first dielectric material layer 306 is formed, patterned and etched to create openings or voids for bit lines BL₁₁, BL₂₁, BL₃₁. The openings or voids then may be filled with conductive layer 400 (and/or a conductive seed, conductive fill and/or barrier layer if needed). Conductive material layer 400 then may be planarized to form planar surface 402.

Following planarization, the semiconductor material used to form vertical Fe-FETs T₁₁₁-T₃₃₁ is formed over planarized top surface 402 of substrate 302. In some embodiments, each vertical Fe-FET is formed from a polycrystalline semiconductor material such as polysilicon, an epitaxial growth silicon, a polycrystalline silicon-germanium alloy, polygermanium or any other suitable material. Alternatively, vertical Fe-FETs T₁₁₁-T₃₃₁ may be formed from a wide band-gap semiconductor material, such as ZnO, InGaZnO, or SiC, which may provide a high breakdown voltage, and typically may be used to provide junctionless FETs. Persons of ordinary skill in the art will understand that other materials may be used.

In some embodiments, each vertical Fe-FETs T₁₁₁-T₃₃₁. may include a first region (e.g., n+ polysilicon), a second region (e.g., p polysilicon) and a third region (e.g., n+ polysilicon) to form drain/source, body, and source/drain regions, respectively, of a vertical Fe-FET. For example, a heavily doped n+ polysilicon layer 312a may be deposited on planarized top surface 402. In some embodiments, n+ polysilicon layer 312a is in an amorphous state as deposited. In other embodiments, n+ polysilicon layer 312a is in a polycrystalline state as deposited. CVD or another suitable process may be employed to deposit n+ polysilicon layer 312a.

In an embodiment, n+ polysilicon layer 312a may be formed, for example, from about 10 to about 50 nm, of phosphorus or arsenic doped silicon having a doping concentration of about 10²¹ cm⁻³. Other layer thicknesses, doping types and/or doping concentrations may be used. N+ polysilicon layer 312a may be doped in situ, for example, by flowing a donor gas during deposition. Other doping methods may be used (e.g., implantation).

After deposition of n+ silicon layer 312a, a doped p-type silicon layer 312b may be formed over n+ polysilicon layer 312a. P-type silicon may be either deposited and doped by ion implantation or may be doped in situ during deposition to form a p-type silicon layer 312b. For example, an intrinsic silicon layer may be deposited on n+ polysilicon layer 312a, and a blanket p-type implant may be employed to implant boron a predetermined depth within the intrinsic silicon layer. Example implantable molecular ions include BF₂, BF₃, B and the like. In some embodiments, an implant dose of about 1-10×10¹³ ions/cm² may be employed. Other implant species and/or doses may be used. Further, in some embodiments, a diffusion process may be employed. In an embodiment, the resultant p-type silicon layer 312b has a thickness of from about 80 to about 400 nm, although other p-type silicon layer sizes may be used.

Following formation of p-type silicon layer 312b, a heavily doped n+ polysilicon layer 312c is deposited on p-type silicon layer 312b. In some embodiments, n+ polysilicon layer 312c is in an amorphous state as deposited. In other embodiments, n+ polysilicon layer 312c is in a polycrystalline state as deposited. CVD or another suitable process may be employed to deposit n+ polysilicon layer 312c.

In an embodiment, n+ polysilicon layer 312c may be formed, for example, from about 10 to about 50 nm of phosphorus or arsenic doped silicon having a doping concentration of about 10²¹ cm⁻³. Other layer thicknesses, doping types and/or doping concentrations may be used. N+ polysilicon layer 312c may be doped in situ, for example, by flowing a donor gas during deposition. Other doping methods may be used (e.g., implantation). Persons of ordinary skill in the art will understand that silicon layers 312a, 312b and 312c alternatively may be doped p+/n/p+, respectively, or may be doped with a single type of dopant to produce junctionless-FETs.

Following formation of n+ polysilicon layer 312c, a hard mask material layer 404 is deposited on n+ polysilicon layer 312c, resulting in the structure shown in FIGS. 4B1-4B2. Hard mask material layer 404 may include any suitable hard mask material such as silicon nitride, amorphous carbon, or the like deposited by any suitable method (e.g., CVD, PVD, etc.). In at least one embodiment, hard mask material layer 404 may be between about 30 nm and about 80 nm of silicon nitride. Other hard mask materials and/or thicknesses may be used.

Hard mask material layer 404 and silicon layers 312a, 312b and 312c are patterned and etched to form rows 406 of silicon layers 312a, 312b and 312c and hard mask material layer 404, resulting in the structure shown in FIGS. 4C1-4C3. For example, hard mask material layer 404 and silicon layers 312a, 312b and 312c may be patterned and etched using conventional lithography techniques, with wet or dry etch processing.

Hard mask material layer 404 and silicon layers 312a, 312b and 312c may be patterned and etched in a single pattern/etch procedure or using separate pattern/etch steps. Any suitable masking and etching process may be used to form vertical transistor pillars. For example, silicon layers may be patterned with about 1 to about 1.5 micron, more preferably about 1.2 to about 1.4 micron, of photoresist (“PR”) using standard photolithographic techniques. Thinner PR layers may be used with smaller critical dimensions and technology nodes. In some embodiments, an oxide hard mask may be used below the PR layer to improve pattern transfer and protect underlying layers during etching.

In some embodiments, after etching, rows 406 may be cleaned using a dilute hydrofluoric/sulfuric acid clean. Such cleaning may be performed in any suitable cleaning tool, such as a Raider tool, available from Semitool of Kalispell, Montana. Example post-etch cleaning may include using ultra-dilute sulfuric acid (e.g., about 1.0-1.8 wt %) for about 60 seconds and/or ultra-dilute hydrofluoric (“HF”) acid (e.g., about 0.4-0.6 wt %) for 60 seconds. Megasonics may or may not be used. Other clean chemistries, times and/or techniques may be employed.

A second dielectric material layer 308 is deposited conformally over substrate 302, and forms on sidewalls of rows 406, resulting in the structure shown in FIGS. 4D1-4D2. For example, between about 0.5 nm to about 10 nm of silicon oxynitride may be deposited. Other dielectric materials such as silicon dioxide or other dielectric materials and/or dielectric material layer thicknesses may be used.

An optional spacer dielectric material 310 may be deposited anisotropically over substrate 302, filling voids between on rows 406. For example, between approximately 20 nm to about 90 nm of silicon dioxide may be deposited on top of second dielectric material layer 308 on rows 406, and between approximately 10 nm to about 90 nm of silicon dioxide may be deposited on bottom of trenches of second dielectric material layer 308 between rows 406, resulting in the structure shown in FIGS. 4E1-4E2. Other dielectric materials, thicknesses and deposition techniques may be used.

Spacer dielectric material 310 is then isotropically etched, for example by a wet etch process, removing spacer dielectric material layer 310 from tops and sidewalls of second dielectric material layer 308, and leaving between about 10 nm and about 70 nm of spacer dielectric material layer 310 on bottom of trenches of second dielectric material layer 308 between rows 406, resulting in the structure shown in FIGS. 4F1-4F2. Alternatively, a chemical dry etching (CDE) process can be used to isotropically etch spacer dielectric material 310. Other etch chemistries may be used.

A gate oxide material 314 is deposited conformally (e.g., by atomic layer deposition (ALD)) over substrate 302, and forms on sidewalls second dielectric material layer 308. In an embodiment, gate oxide material 314 includes a ferroelectric oxide material. For example, between about 5 nm to about 20 nm of hafnium oxide may be deposited. The gate oxide may be doped with, for example, one or more of silicon, aluminum, zirconium, yttrium, gadolinium, calcium, cerium, dysprosium, erbium, germanium, scandium, and tin during the deposition step. In an embodiment, the doping can be performed by using a precursor containing the dopant during the ALD step. In an embodiment, the ALD step includes depositing alternating thin layers of HfO₂ and SiO₂, with the relative thickness of each layer determining the amount of the silicon dopant incorporated into the final deposited film. Other oxide materials, dopants and/or thicknesses may be used. In an embodiment, annealing may be performed to crystallize the deposited gate oxide material. An anisotropic etch is used to remove lateral portions of gate oxide material, leaving only sidewall portions of gate oxide material 314, resulting in the structure shown in FIGS. 4G1-4G2.

A gate electrode material is deposited over substrate 302. For example, approximately 5 nm to about 30 nm of titanium nitride, or other similar conductive material may be deposited. Other conductive materials and/or thicknesses may be used. The as-deposited gate electrode material is subsequently etched back to form gate electrodes 408, resulting in the structure shown in FIGS. 4H1-4H2. Gate electrodes 408 are disposed on opposite sides of the vertical stack of silicon layers 312a, 312b and 312c. Other conductive materials and/or thicknesses may be used for gate electrodes 408. Gate electrodes 408 will be used to form word lines WL₁₁ₐ-WL_{33b}.

An anisotropic etch is used to remove lateral portions of second dielectric material layer 308, leaving only sidewall portions of second dielectric material layer 308. Next, hard mask material layer 404 and silicon layers 312a, 312b and 312c are patterned and etched to form vertical transistor pillars, resulting in the structure shown in FIGS. 411-413. For example, hard mask material layer 404 and silicon layers 312a, 312b and 312c may be patterned and etched using conventional lithography techniques, with wet or dry etch processing. In an embodiment, hard mask material layer 404 and silicon layers 312a, 312b and 312c are patterned and etched to form vertical transistor pillars disposed above bit lines BL₁₁, BL₂₁, BL₃₁. The vertical transistor pillars will be used to form vertical FeFETs T₁₁₁-T₃₃₁.

A third dielectric material layer 316 is deposited over substrate 302, filling voids between the vertical transistor pillars, gate electrodes 408, and second dielectric material layer 308. For example, approximately 5000 to about 8000 angstroms of silicon dioxide may be deposited and planarized using chemical mechanical polishing or an etch-back process to form planar top surface 410, resulting in the structure shown in FIGS. 4J1-4J3.

A conductive material layer 412 is deposited over planar surface 410. Conductive material layer 412 may include any suitable conductive material such as tungsten or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive material layer 412 may be between about 20 nm and about 250 nm of tungsten. Other conductive material layers and/or thicknesses may be used. In some embodiments, an adhesion layer (not shown), such as titanium nitride or other similar adhesion layer material, may be disposed between third regions 312c and conductive material layer 412, and/or between conductive material layer 412 and subsequent material layers.

Persons of ordinary skill in the art will understand that adhesion layers may be formed by PVD or another method on conductive material layers. For example, adhesion layers may be between about 2 nm and about 50 nm, and in some embodiments about 10 nm, of titanium nitride or another suitable adhesion layer such as tantalum nitride, tungsten nitride, tungsten, molybdenum, combinations of one or more adhesion layers, or the like. Other adhesion layer materials and/or thicknesses may be employed.

Following formation of conductive material layer 412, conductive material layer 412 is patterned and etched. For example, conductive material layer 412 may be patterned and etched using conventional lithography techniques, with a soft or hard mask, and wet or dry etch processing. In at least one embodiment, conductive material layer 412 is patterned and etched to form source lines SL₁₁, SL₂₁, SL₃₁. In an embodiment, source lines SL₁₁, SL₂₁, SL₃₁ are substantially parallel to and aligned with bit lines BL₁₁, BL₂₁, BL₃₁. In other embodiments, source lines SL₁₁, SL₂₁, SL₃₁ may be perpendicular to bit lines BL₁₁, BL₂₁, BL₃₁. Example widths for source lines SL₁₁, SL₂₁, SL₃₁ and/or spacings between source lines SL₁₁, SL₂₁, SL₃₁ range between about 38 nm to about 100 nm, although other conductor widths and/or spacings may be used.

After source lines SL₁₁, SL₂₁, SL₃₁ have been formed, a fourth dielectric material layer 318 is formed over substrate 302 to fill the voids between source lines SL₁₁, SL₂₁, SL₃₁. For example, approximately 300-700 nm of silicon dioxide may be deposited on the substrate 302 and planarized using chemical mechanical polishing or an etchback process to form a planar surface 414. Other dielectric materials such as silicon nitride, silicon oxynitride, low K dielectrics, etc., and/or other dielectric material layer thicknesses may be used. Example low K dielectrics include carbon doped oxides, silicon carbon layers, or the like.

In other embodiments, source lines SL₁₁, SL₂₁, SL₃₁ may be formed using a damascene process in which fourth dielectric material layer 318 is formed, patterned and etched to create openings or voids for source lines SL₁₁, SL₂₁, SL₃₁. The openings or voids then may be filled with conductive layer 412 (and/or a conductive seed, conductive fill and/or barrier layer if needed). Conductive material layer 412 then may be planarized to form planar surface 414.

Thus, as described above, one embodiment includes a memory cell that includes a vertical transistor having a gate oxide that includes a ferroelectric material.

One embodiment includes a memory array including bit lines disposed in parallel along a first axis, source lines disposed in parallel along the first axis, word lines disposed in parallel substantially perpendicular to the first axis, and memory elements. Each memory element includes a vertical ferroelectric transistor disposed between a corresponding one of bit lines and a corresponding one of source lines, and is to a corresponding one of word lines.

One embodiment includes a monolithic three-dimensional memory array including a first memory level disposed above a substrate, and a second memory level disposed above the first memory level. The first memory level includes first bit lines disposed in parallel along a first axis, first source lines disposed in parallel along the first axis and above the first bit lines, first word lines disposed in parallel substantially perpendicular to the first axis, and first memory elements, each first memory element including a vertical ferroelectric transistor disposed between a corresponding one of the first bit lines and a corresponding one of the first source lines, and each coupled to a corresponding one of the first word lines. The second memory level includes second bit lines disposed in parallel along the first axis and above the plurality of first source lines, second word lines disposed in parallel substantially perpendicular to the first axis, and second memory elements, each second memory element including a vertical ferroelectric transistor disposed between a corresponding one of the second bit lines and a corresponding one of the first source lines, and each coupled to a corresponding one of the second word lines.

The foregoing detailed description has been presented for purposes of illustration and description. It is not intended to be exhaustive or be limited to the precise form disclosed. Many modifications and variations are possible in light of the above description. The described embodiments were chosen to best explain the principles of the technology and its practical application, to thereby enable others skilled in the art to best utilize the technology in various embodiments and with various modifications as are suited to the particular use contemplated. The scope of the technology is defined by the claims appended hereto.

1. A memory element comprising:
a vertical transistor comprising a gate oxide comprising a ferroelectric material, and two separate and distinct gate electrodes,
wherein the vertical transistor comprises a long axis in a first direction, and the gate electrodes each comprise a long axis in a second direction substantially perpendicular to the first direction.

2. The memory element of claim 1, wherein the gate oxide comprises hafnium oxide.

3. The memory element of claim 1, wherein the gate oxide comprises hafnium oxide doped with one or more of silicon, aluminum, zirconium, yttrium, gadolinium, calcium, cerium, dysprosium, erbium, germanium, scandium, and tin.

4. The memory element of claim 1, comprising a first gate electrode and a second gate electrode.

5. The memory element of claim 4, wherein the first gate electrode and a second gate electrode are disposed on opposite sides of the vertical transistor.

6. The memory element of claim 1, wherein the memory element comprises the vertical transistor and no other circuit elements.

7. The memory element of claim 1, wherein the memory element can be configured as a single memory cell or two memory cells.

8. The memory element of claim 1, wherein the vertical transistor comprises:
a first electrode coupled to a bit line; and
a second electrode coupled to a source line.

9. The memory element of claim 1, wherein the vertical transistor comprises a field effect transistor.

10. The memory element of claim 1, wherein the vertical transistor comprises a first region having a first conductivity type, a second region having a second conductivity type above the first region, and a third region having the first conductivity type above the second region.

11. A memory array comprising:
a plurality of bit lines disposed in parallel along a first axis;
a plurality of source lines disposed in parallel along the first axis;
a plurality of word lines disposed in parallel substantially perpendicular to the first axis; and
a plurality of memory elements, each memory element comprising a vertical ferroelectric transistor disposed between a corresponding one of the bit lines and a corresponding one of the source lines, and each memory element coupled to a corresponding one of the word lines
wherein:
each vertical ferroelectric transistor comprises two separate and distinct gate electrodes; and
each vertical ferroelectric transistor comprises a long axis in a first direction, and the gate electrodes each comprise a long axis in a second direction substantially perpendicular to the first direction.

12. The memory array of claim 11, wherein each of the source lines are disposed above the bit lines, and the vertical ferroelectric transistors are disposed above the bit lines.

13. The memory array of claim 11, wherein each of the bit lines are disposed above the source lines, and the vertical ferroelectric transistors are disposed above the source lines.

14. The memory array of claim 11, wherein each of the vertical ferroelectric transistors comprises a gate oxide including hafnium oxide.

15. The memory array of claim 11, wherein each of the vertical ferroelectric transistors comprises a first gate electrode and a second gate electrode.

16. The memory array of claim 15, wherein the first gate electrode and a second gate electrode are disposed on opposite sides of the vertical ferroelectric transistor.

17. The memory array of claim 11, wherein each memory element comprises the vertical ferroelectric transistor and no other circuit elements.

18. The memory array of claim 11, wherein each memory element can be configured as a single memory cell or two memory cells.

19. A monolithic three-dimensional memory array comprising:
a first memory level disposed above a substrate, the first memory level comprising:
a plurality of first bit lines disposed in parallel along a first axis;
a plurality of first source lines disposed in parallel along the first axis and above the plurality of first bit lines;
a plurality of first word lines disposed in parallel substantially perpendicular to the first axis; and
a plurality of first memory elements, each first memory element comprising a first vertical ferroelectric transistor disposed between a corresponding one of the first bit lines and a corresponding one of the first source lines, and each first memory element coupled to a corresponding one of the first word lines,
wherein each first vertical ferroelectric transistor comprises two separate and distinct first gate electrodes, and each first ferroelectric vertical transistor comprises a long axis in a first direction, and the first gate electrodes each comprise a long axis in a second direction substantially perpendicular to the first direction; and
a second memory level disposed above the first memory level, the second memory level comprising:
a plurality of second bit lines disposed in parallel along the first axis and above the plurality of first source lines;
a plurality of second word lines disposed in parallel substantially perpendicular to the first axis; and
a plurality of second memory elements, each second memory element comprising a second vertical ferroelectric transistor disposed between a corresponding one of the second bit lines and a corresponding one of the first source lines, and each second memory element coupled to a corresponding one of the second word lines
wherein each second vertical ferroelectric transistor comprises two separate and distinct gate electrodes, and each second ferroelectric vertical transistor comprises a long axis in the first direction, and the first gate electrodes each comprise a long axis in the second direction.

20. The monolithic three-dimensional memory array of claim 19, wherein each of the vertical ferroelectric transistors comprises a gate oxide including hafnium oxide.
